(19) United States
(12) Patent Application Publication
(10) Pub. No.: US 2026/0182062 A1
(43) Pub. Date: Jun. 25, 2026

(54) SOLID-STATE IMAGING DEVICE

(71) Applicant: SONY SEMICONDUCTOR SOLUTIONS CORPORATION, KANAGAWA (JP)

(72) Inventors: RIO UEI, KANAGAWA (JP); HITOSHI TSUNO, KANAGAWA (JP); HIDEAKI TOGASHI, KANAGAWA (JP)

(21) Appl. No.: 19/127,003

(22) PCT Filed: Sep. 19, 2023
(86) PCT No.: PCT/JP2023/033839

§ 371 Date: May 2, 2025

(30) Foreign Application Priority Data
Nov. 10, 2022 (JP) 2022-180029

(51) Int. Cl. H10F 39/00; H10F 39/18

(52) U.S. Cl. CPC H10F 39/807; H10F 39/18; H10F 39/8023

(57) ABSTRACT

A solid-state imaging device includes a plurality of pixels arranged, and a partition wall. The pixels each includes a first photoelectric converter, an optical filter, and a second photoelectric converter. The first photoelectric converter is provided in a base, and converts light in a first wavelength range into electric charge. The optical filter is provided on the first photoelectric converter on a side opposite to the base, has a side surface surrounded by an insulator, and allows the light in the first wavelength range to pass therethrough. The second photoelectric converter is provided on the optical filter on a side opposite to the first photoelectric converter, and converts light in a second wavelength range different from the first wavelength range into electric charge. The partition wall is provided in a region corresponding to between the optical filters adjacent to each other of the pixels, and in which light leakage is smaller than light leakage in the insulator.

### TECHNICAL FIELD

The present disclosure relates to a solid-state imaging device.

### BACKGROUND ART

PTL 1 discloses an image sensor. In the image sensor, a plurality of pixels on which light is to be incident is arranged. The pixels each includes a semiconductor photodiode formed on a substrate, a color filter on the semiconductor photodiode, and an organic photodiode on the color filter. The semiconductor photodiode and the color filter are provided for each of the pixels. The organic photodiode is provided across a plurality of pixels.

### CITATION LIST

### Patent Literature

PTL 1: US Unexamined Patent Application Publication No. 2019/0027539 A1

### SUMMARY OF THE INVENTION

In the image sensor described above, an insulating film is formed around a side surface of the color filter; however, light leakage into adjacent pixels is not taken into consideration. It is therefore desirable to develop a solid-state imaging device that makes it possible to prevent light leakage into adjacent pixels.

A solid-state imaging device according to a first aspect of the present disclosure includes a plurality of pixels arranged, and a partition wall. The pixels each includes a first photoelectric converter, an optical filter, and a second photoelectric converter. The first photoelectric converter is provided in a base, and converts light in a first wavelength range into electric charge. The optical filter is provided on the first photoelectric converter on a side opposite to the base, has a side surface surrounded by an insulator, and allows the light in the first wavelength range to pass therethrough. The second photoelectric converter is provided on the optical filter on a side opposite to the first photoelectric converter, and converts light in a second wavelength range different from the first wavelength range into electric charge. The partition wall is provided in a region corresponding to between the optical filters adjacent to each other of the pixels, and in which light leakage is smaller than light leakage in the insulator.

A solid-state imaging device according to a second aspect of the present disclosure further includes a through electrode that penetrates in a thickness direction of the optical filter from the second photoelectric converter toward a side of the first photoelectric converter, in the solid-state imaging device according to the first aspect. The through electrode is provided in a middle where the partition wall extends.

### BRIEF DESCRIPTION OF THE DRAWINGS

FIG. 1 is a circuit block diagram describing a system configuration of a solid-state imaging device according to a first embodiment of the present disclosure.

FIG. 2 is a circuit diagram of a pixel and pixel circuits of the solid-state imaging device illustrated in FIG. 1.

FIG. 3 is a specific longitudinal cross-sectional configuration diagram of the pixel illustrated in FIGS. 1 and 2.

FIG. 4 is a first step cross-sectional view of a manufacturing method of the solid-state imaging device according to the first embodiment for each of steps.

FIG. 5 is a second step cross-sectional view.

FIG. 6 is a third step cross-sectional view.

FIG. 7 is a fourth step cross-sectional view.

FIG. 8 is a fifth step cross-sectional view.

FIG. 9 is a sixth step cross-sectional view.

FIG. 10 is a seventh step cross-sectional view.

FIG. 11 is a longitudinal cross-sectional configuration diagram, corresponding to FIG. 3, of a pixel of a solid-state imaging device according to a second embodiment of the present disclosure.

FIG. 12 is a longitudinal cross-sectional configuration diagram, corresponding to FIG. 3, of a pixel of a solid-state imaging device according to a third embodiment of the present disclosure.

FIG. 13 is a longitudinal cross-sectional configuration diagram, corresponding to FIG. 3, of a pixel of a solid-state imaging device according to a fourth embodiment of the present disclosure.

FIG. 14 is a longitudinal cross-sectional configuration diagram, corresponding to FIG. 3, of a pixel of a solid-state imaging device according to a fifth embodiment of the present disclosure.

FIG. 15 is a longitudinal cross-sectional configuration diagram, corresponding to FIG. 3, of a pixel of a solid-state imaging device according to a sixth embodiment of the present disclosure.

FIG. 16 is a longitudinal cross-sectional configuration diagram, corresponding to FIG. 3, of a pixel of a solid-state imaging device according to a seventh embodiment of the present disclosure.

FIG. 17 is a longitudinal cross-sectional configuration diagram, corresponding to FIG. 3, of a pixel of a solid-state imaging device according to an eighth embodiment of the present disclosure.

FIG. 18 is a longitudinal cross-sectional configuration diagram, corresponding to FIG. 3, of a pixel of a solid-state imaging device according to a ninth embodiment of the present disclosure.

FIG. 19 is a longitudinal cross-sectional configuration diagram, corresponding to FIG. 3, of a pixel of a solid-state imaging device according to a tenth embodiment of the present disclosure.

FIG. 20 is a specific planar configuration diagram of a pixel of a solid-state imaging device according to an eleventh embodiment of the present disclosure.

FIG. 21 is a planar configuration diagram, corresponding to FIG. 20, of a pixel of a solid-state imaging device according to a twelfth embodiment of the present disclosure.

FIG. 22 is a planar configuration diagram, corresponding to FIG. 20, of a pixel of a solid-state imaging device according to a thirteenth embodiment of the present disclosure.

FIG. 23 is a planar configuration diagram, corresponding to FIG. 20, of a pixel of a solid-state imaging device according to a fourteenth embodiment of the present disclosure.

FIG. 24 is a planar configuration diagram, corresponding to FIG. 20, of a pixel of a solid-state imaging device according to a fifteenth embodiment of the present disclosure.

FIG. 25 is a planar configuration diagram, corresponding to FIG. 20, of a pixel of a solid-state imaging device according to a sixteenth embodiment of the present disclosure.

FIG. 26 is a planar configuration diagram, corresponding to FIG. 20, of a pixel of a solid-state imaging device according to a seventeenth embodiment of the present disclosure.

FIG. 27 is a planar configuration diagram, corresponding to FIG. 20, of a pixel of a solid-state imaging device according to an eighteenth embodiment of the present disclosure.

FIG. 28 is a block diagram depicting an example of schematic configuration of a vehicle control system.

FIG. 29 is a diagram of assistance in explaining an example of installation positions of an outside-vehicle information detecting section and an imaging section.

FIG. 30 is a view depicting an example of a schematic configuration of an endoscopic surgery system.

FIG. 31 is a block diagram depicting an example of a functional configuration of a camera head and a camera control unit (CCU).

### MODES FOR CARRYING OUT THE INVENTION

Hereinafter, description is given in detail of embodiments of the present disclosure with reference to the drawings. It is to be noted that the description is given in the following order.

### 1. First Embodiment

A first embodiment is a first example in which the present technology is applied to a solid-state imaging device. The first embodiment describes a system configuration of the solid-state imaging device, configurations of a pixel and a pixel circuit, a specific longitudinal cross-sectional configuration of the solid-state imaging device, a manufacturing method of the solid-state imaging device.

### 2. Second Embodiment

A second embodiment is a second example in which a structure of a partition wall is changed in the solid-state imaging device according to the first embodiment.

### 3. Third Embodiment

A third embodiment is a third example in which the structure of the partition wall is changed in the solid-state imaging device according to the first embodiment.

### 4. Fourth Embodiment

A fourth embodiment is a fourth example in which the structure of the partition wall is changed in the solid-state imaging device according to the first embodiment.

### 5. Fifth Embodiment

A fifth embodiment is a fifth example in which the structure of the partition wall is changed in the solid-state imaging device according to the first embodiment.

### 6. Sixth Embodiment

A sixth embodiment is a sixth example in which the structure of the partition wall is changed in the solid-state imaging device according to the first embodiment.

### 7. Seventh Embodiment

A seventh embodiment is a seventh example in which the structure of the partition wall is changed in the solid-state imaging device according to the first embodiment.

### 8. Eighth Embodiment

An eighth embodiment is an eighth example in which the structure of the partition wall is changed in the solid-state imaging device according to the first embodiment.

### 9. Ninth Embodiment

A ninth embodiment is a ninth example in which the structure of the partition wall is changed in the solid-state imaging device according to the first embodiment.

### 10. Tenth Embodiment

A tenth embodiment is a tenth example in which the structure of the partition wall is changed in the solid-state imaging device according to the first embodiment.

### 11. Eleventh Embodiment

An eleventh embodiment is a first example that describes configurations of the partition wall and a through electrode with respect to the partition wall in the solid-state imaging device according to any of the first to tenth embodiments.

### 12. Twelfth Embodiment

A twelfth embodiment is a second example in which the configurations of the partition wall and the through electrode with respect to the partition wall are changed in the solid-state imaging device according to the eleventh embodiment.

### 13. Thirteenth Embodiment

A thirteenth embodiment is a third example in which the configurations of the partition wall and the through electrode with respect to the partition wall are changed in the solid-state imaging device according to the eleventh embodiment.

### 14. Fourteenth Embodiment

A fourteenth embodiment is a fourth example in which the configurations of the partition wall and the through electrode with respect to the partition wall are changed in the solid-state imaging device according to the eleventh embodiment.

### 15. Fifteenth Embodiment

A fifteenth embodiment is a fifth example in which the configurations of the partition wall and the through electrode with respect to the partition wall are changed in the solid-state imaging device according to the eleventh embodiment.

### 16. Sixteenth Embodiment

A sixteenth embodiment is a sixth example in which the configurations of the partition wall and the through electrode with respect to the partition wall are changed in the solid-state imaging device according to the eleventh embodiment.

### 17. Seventeenth Embodiment

A seventeenth embodiment is a seventh example in which the configurations of the partition wall and the through electrode with respect to the partition wall are changed in the solid-state imaging device according to the eleventh embodiment.

### 18. Eighteenth Embodiment

An eighteenth embodiment is an eighth example in which the configurations of the partition wall and the through electrode with respect to the partition wall are changed in the solid-state imaging device according to the eleventh embodiment.

### 19. Example of Application to Mobile Body

The application example describes an example in which the present technology is applied to a vehicle control system that is an example of a mobile body control system.

### 20. Example of Application to Endoscopic Surgery System

The application example describes an example in which the present technology is applied to an endoscopic surgery system.

### 21. Other Embodiments

### 1. First Embodiment

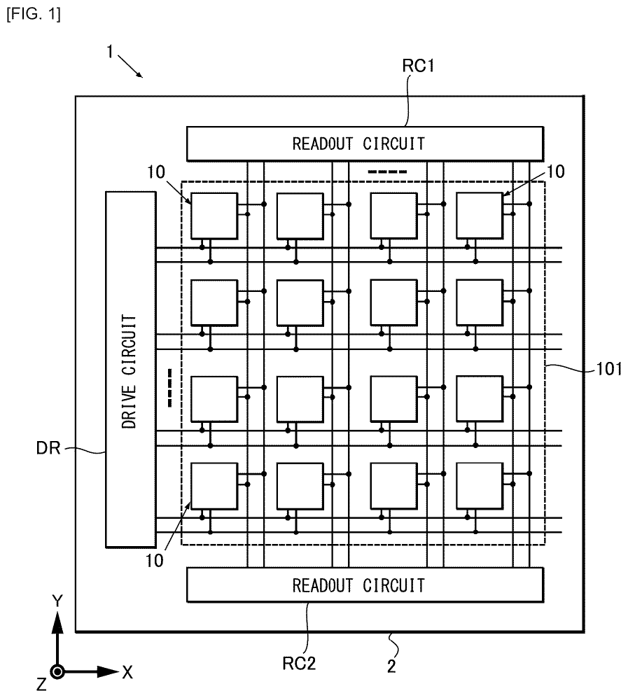

Description is given of a solid-state imaging device 1 according to the first embodiment of the present disclosure with reference to FIGS. 1 to 10.

Here, an arrow-X direction indicated as appropriate in the drawings indicates one planar direction of the solid-state imaging device 1 placed on a plane for convenience. An arrow-Y direction indicates another planar direction orthogonal to the arrow-X direction. In addition, an arrow-Z direction indicates an upward direction orthogonal to the arrow-X direction and the arrow-Y direction. That is, the arrow-X direction, the arrow-Y direction, and the arrow-Z direction exactly coincide with an X-axis direction, a Y-axis direction, and a Z-axis direction, respectively, of a three-dimensional coordinate system.

It is to be noted that these directions are each indicated to aid understanding of descriptions, and are not intended to limit directions used in the present technology.

### [Configuration of Solid-State Imaging Device 1]

### (1) Overall System Configuration of Solid-State Imaging Device 1

FIG. 1 illustrates an example of a circuit block for describing a system configuration of the solid-state imaging device 1.

The solid-state imaging device 1 includes a light reception region 101 in a middle portion of a base 2 as viewed in the arrow-Z direction (hereinafter, simply referred to as “in a plan view”). A plurality of pixels 10 is regularly arranged in the light reception region 101.

A plurality of pixels 10 is arranged in the arrow-X direction as a first direction, and a plurality of pixels 10 is arranged in the arrow-Y direction as a second direction. That is, the pixels 10 are arranged in a matrix. The pixels 10 each convert incident light into electric charge as a signal.

In the solid-state imaging device 1, peripheral circuits are further provided. The peripheral circuits include at least a readout circuit RC1, a readout circuit RC2, and a drive circuit DR.

As will be described later, one pixel 10 includes two photoelectric converters. The readout circuit RC1 includes, for example, a pixel circuit that reads, as a signal, electric charge converted in one of the photoelectric converters. The readout circuit RC2 includes, for example, a pixel circuit that reads, as a signal, electric charge converted in another photoelectric converter.

The drive circuit DR outputs a drive signal that drives the photoelectric converters of the pixel 10.

### (2) Circuit Configurations of Pixel 10, Pixel Circuit PC1 and Pixel Circuit PC2

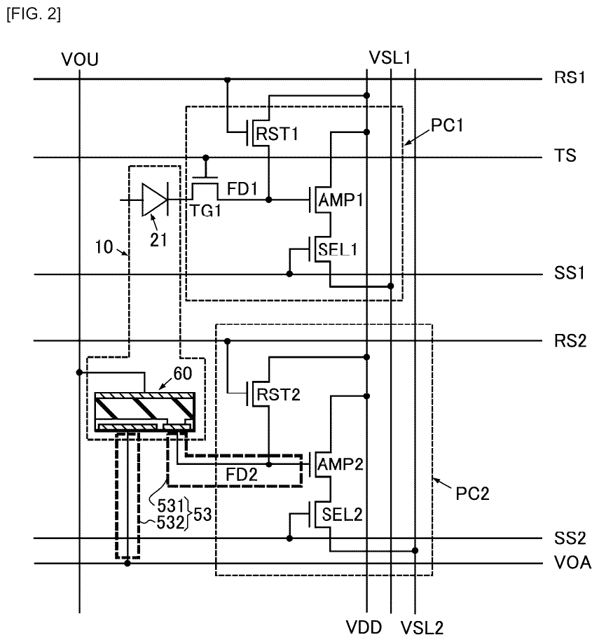

FIG. 2 illustrates an example of circuit configurations of the pixel 10, the pixel circuit PC1, and the pixel circuit PC2.

The pixel 10 includes two photoelectric converters, that is, a first photoelectric converter 21 and a second photoelectric converter 60. A wavelength band of light to be converted in the first photoelectric converter 21 is different from a wavelength band of light to be converted in the second photoelectric converter 60.

The first photoelectric converter 21 includes a semiconductor photodiode. The first photoelectric converter 21 generates electric charge depending on an amount of incident light. The electric charge is transmitted as a signal to the pixel circuit PC1.

The pixel circuit PC1 is coupled to the first photoelectric converter 21. The pixel circuit PC1 here includes a transfer transistor TG1, a reset transistor RST1, an amplification transistor AMP1, and a selection transistor SEL1.

Of a pair of main electrodes of the transfer transistor TG1, one main electrode is coupled to the first photoelectric converter 21. Another main electrode is coupled to a gate electrode of the amplification transistor AMP1 through a floating diffusion FD1. A control signal line (a horizontal signal line) TS that transfers a control line is coupled to a gate electrode of the transfer transistor TG1.

Of a pair of main electrodes of the reset transistor RST1, one main electrode is coupled to the floating diffusion FD1. Another main electrode is coupled to a power supply voltage VDD. A reset signal line RS1 that transfers a reset signal is coupled to a gate electrode of the reset transistor RST1.

Of a pair of main electrodes of the amplification transistor AMP1, one main electrode is coupled to the power supply voltage VDD. Another main electrode is coupled to one main electrode of a pair of main electrodes of the selection transistor SEL1.

Another main electrode of the selection transistor SEL1 is coupled to an output signal line (a vertical signal line) VSL1. A gate electrode of the selection transistor SEL1 is coupled to a selection signal line SS1.

Here, the control signal line TS is coupled to the drive circuit DR (see FIG. 1). In addition, the output signal line VSL1 is coupled to the readout circuit RC1 (see FIG. 1).

The second photoelectric converter 60 here includes an organic photodiode. The second photoelectric converter 60 generates electric charge depending on the amount of incident light. The electric charge is transmitted as a signal to the pixel circuit PC2.

The pixel circuit PC2 is coupled to the second photoelectric converter 60. The pixel circuit PC2 here includes a reset transistor RST2, an amplification transistor AMP2, and a selection transistor SEL2.

A drive signal line VOA and a power supply voltage line VOU are coupled to the second photoelectric converter 60. The drive signal line VOA supplies a drive voltage to one electrode of each pixel 10. The power supply voltage line VOU supplies a fixed voltage to other electrodes of a plurality of pixels 10.

The second photoelectric converter 60 is coupled to a gate electrode of the amplification transistor AMP2 through a floating diffusion FD2.

Of a pair of main electrodes of the reset transistor RST2, one main electrode is coupled to the floating diffusion FD2. Another main electrode is coupled to the power supply voltage VDD. A reset signal line RS2 that transfers a reset signal is coupled to a gate electrode of the reset transistor RST2.

Of a pair of main electrodes of the amplification transistor AMP2, one main electrode is coupled to the power supply voltage VDD. Another main electrode is coupled to one main electrode of a pair of main electrodes of the selection transistor SEL2.

Another main electrode of the selection transistor SEL2 is coupled to an output signal line (a vertical signal line) VSL2. A gate electrode of the selection transistor SEL2 is coupled to a selection signal line SS2.

Here, the drive signal line VOA is coupled to the drive circuit DR (see FIG. 1). In addition, the output signal line VSL2 is coupled to the readout circuit RC2 (see FIG. 1).

Here, in the present technology, a through electrode 53 (see FIG. 20 and subsequent drawings) is described as a component in the solid-state imaging devices 1 according to the eleventh and subsequent embodiments. The through electrode 53 includes two kinds of through electrodes, that is, a first through electrode 531 and a second through electrode 532.

The first through electrode 531 configures a portion of the floating diffusion FD2 that couples one electrode of the second photoelectric converter 60 and the pixel circuit PC2 to each other. In addition, the second through electrode 532 configures a coupling wiring that couples another electrode of the second photoelectric converter 60 and the drive signal line VOA to each other. In description of the present technology, when differentiation between the first through electrode 531 and the second through electrode 532 is not particularly necessary, the first through electrode 531 and the second through electrode 532 are simply collectively referred to as through electrodes 53.

The solid-state imaging device 1 further includes an unillustrated image processing circuit. Each of the pixel circuit PC1 and the pixel circuit PC2 is coupled to the image processing circuit.

The image processing circuit includes, for example, an analog-to-digital converter (ADC) and a digital signal processor (DSP).

The electric charge converted from light in the pixel 10 is an analog signal. The analog signal is subjected to amplification processing in each of the pixel circuit PC1 and the pixel circuit PC2. The ADC converts an analog signal outputted from each of the pixel circuit PC1 and the pixel circuit PC2 into a digital signal. The DSP performs functional processing on the digital signal. That is, the image processing circuit performs signal processing for creating an image.

### (3) Longitudinal Cross-Sectional Configuration of Solid-State Imaging Device 1 and Pixel 10

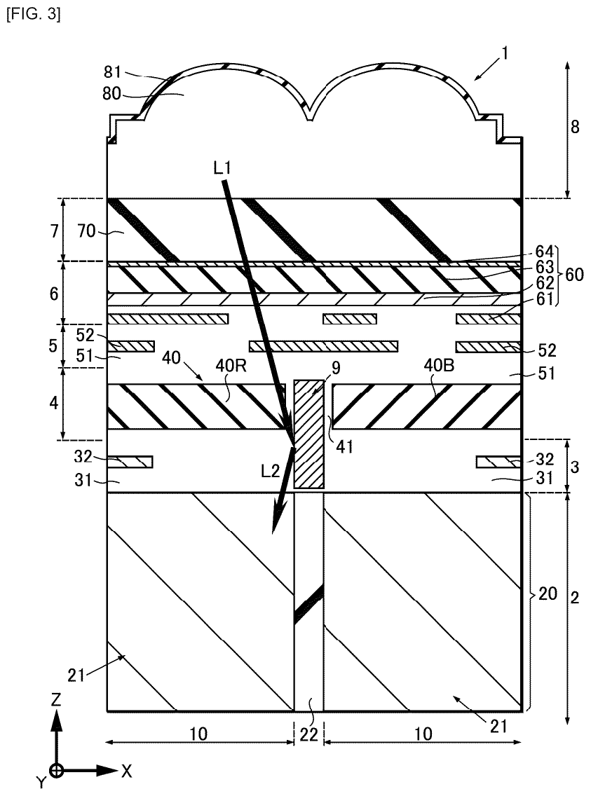

FIG. 3 illustrates an example of a longitudinal cross-sectional configuration of the pixel 10.

In the solid-state imaging device 1, incident light L1 enters the pixel 10 from outside in the arrow-Z direction as viewed in the arrow-Y direction (hereinafter, simply referred to as “in a side view”). The solid-state imaging device 1 includes a base 2, a wiring region 3, a filter region 4, a wiring region 5, a photoelectric conversion region 6, a sealing region 7, and an optical system region 8, which are sequentially stacked in the arrow-Z direction.

Further, the pixel 10 includes the first photoelectric converter 21, an optical filter 40, and the second photoelectric converter 60 as main components.

The solid-state imaging device 1 further includes an optical lens 80.

### (4) Configuration of Base 2

As illustrated in FIG. 3, in the solid-state imaging device 1, the base 2 includes an unillustrated circuit substrate, and a semiconductor substrate 20 stacked on the circuit substrate in the arrow-Z direction.

The circuit substrate is formed by, for example, a single-crystalline Si substrate. The peripheral circuits described above of the solid-state imaging device 1 are mounted on the circuit substrate.

The semiconductor substrate 20 here is formed by a single-crystalline Si substrate, as with the circuit substrate.

### (5) Configuration of First Photoelectric Converter 21

The first photoelectric converter 21 is provided in the semiconductor substrate 20. The first photoelectric converter 21 is provided for each of the pixels 10.

Although a specific configuration of the first photoelectric converter 21 is not illustrated, the first photoelectric converter 21 includes a semiconductor photodiode including a p-type semiconductor region and an n-type semiconductor region. Here, the first photoelectric converter 21 includes, for example, a PIN (Positive Intrinsic Negative) type photodiode.

In the first embodiment, the first photoelectric converter 21 receives incident light in a red light range as a first wavelength range or incident light in a blue light range as the first wavelength range, and generates electric charge photoelectrically converted depending on an amount of received light. The electric charge generated in the first photoelectric converter 21 is outputted to the pixel circuit PC1 (see FIG. 2) mounted on the circuit substrate.

A pixel separation region 22 is provided between the first photoelectric converters 21 of the pixels 10 adjacent to each other in each of the arrow-X direction and the arrow-Y direction. The pixel separation region 22 is formed by, for example, an insulating material such as SiO₂. The pixel separation region 22 is configured to electrically separate the adjacent first photoelectric converters 21 from each other.

### (6) Configuration of Optical Filter 40

The optical filter 40 is provided in the filter region 4. The optical filter 40 is provided on the semiconductor substrate 20 on a side opposite to the circuit substrate with the wiring region 3 interposed therebetween.

Here, the wiring region 3 includes an insulator 31 and a wiring 32 embedded in the insulator 31. The insulator 31 is formed by, for example, an insulating material such as SiO₂. The wiring 32 is used as a wiring that couples the second photoelectric converter 60 and the pixel circuit PC2 to each other (see FIG. 2).

A side surface of the optical filter 40 is surrounded by the insulator 41. A specific material of the insulator 41 will be described later.

The optical filter 40 includes a red filter 40R and a blue filter 40B. The red filter 40R allows the red wavelength range as the first wavelength range to pass therethrough. Likewise, the blue filter 40B allows the blue wavelength range as the first wavelength range to pass therethrough.

The red filter 40R is provided at a position corresponding to one first photoelectric converter 21 of one pixel 10. The red filter 40R allows, for example, light having a wavelength of 585 nm or more and 780 nm or less to pass therethrough.

The blue filter 40B is provided at a position corresponding to one first photoelectric converter 21 of one pixel 10. The blue filter 40B allows, for example, light having a wavelength of 400 nm or more and 500 nm or less to pass therethrough.

Here, the red filter 40R and the blue filter 40B are alternately arranged in each of the arrow-X direction and the arrow-Y direction (for example, see FIG. 20). In the first embodiment, two pixels 10 arranged in the arrow-X direction and two pixels 10 arranged in the arrow-Y direction construct one unit pixel PU. In the unit pixel PU, two red filters 40R are arranged along one diagonal line. In addition, in the unit pixel PU, two blue filters 40B are arranged along another diagonal line orthogonal to the one diagonal line.

The optical filter 40 includes a pigment that colors a resin material. To describe this in detail, it is possible to practically use, as a resin, an organic resin material such as a phthalocyanine derivative.

In addition, the red filter 40R has, for example, a film thickness of 400 nm or more and 850 nm or less. The blue filter 40B has, for example, a film thickness of 200 nm or more and 550 nm or less. The red filter 40R and the blue filter 40B are formed to have respective different film thicknesses for sensitivity adjustment.

### (7) Configuration of Second Photoelectric Converter 60

As illustrated in FIG. 3, the second photoelectric converter 60 is provided on the optical filter 40 on a side opposite to the first photoelectric converter 21 with the wiring region 5 interposed therebetween.

Here, the wiring region 5 includes an insulator 51 and a wiring 52 embedded in the insulator 51. The insulator 51 is formed by, for example, an insulating material such as SiO₂. The wiring 52 is used as a wiring that couples the second photoelectric converter 60 and the pixel circuit PC2 to each other (see FIG. 2).

The second photoelectric converter 60 is provided across a plurality of pixels 10. Here, the second photoelectric converter 60 are provided across all the pixels 10.

The second photoelectric converter 60 includes a first electrode 61, an organic photoelectric conversion layer 63, and a second electrode 64. The second photoelectric converter 60 further includes a charge accumulation/transfer layer 62.

### (7-1) Configuration of First Electrode 61

The first electrode 61 is provided on a side of the optical filter 40, and is formed in a surface portion of the wiring region 5. The first electrode 61 is used as a readout electrode or a lower electrode, and is provided for each of the pixels 10. The first electrode 61 is coupled to the pixel circuit PC2 (see FIG. 2) of the circuit substrate through the wiring 52 of the wiring region 5, the wiring 32 of the wiring region 3, and the like.

For the first electrode 61, for example, an indium oxide-zinc oxide-based oxide (IZO: Indium Zinc Oxide) or indium tin oxide (ITO: Indium Tin Oxide) having electrical conductivity and having transparency is used. The first electrode 61 has, for example, a film thickness of 10 nm or more and 100 nm or less.

### (7-2) Configuration of Organic Photoelectric Conversion Layer 63

The organic photoelectric conversion layer 63 is provided on the first electrode 61 on a side opposite to the optical filter 40. An organic material is used for the organic photoelectric conversion layer 63. As the organic material, there may be used any of a p-type organic semiconductor, an n-type organic semiconductor, a stacked structure of a p-type organic semiconductor and an n-type organic semiconductor, and a mixture (a bulk hetero structure) of a p-type organic semiconductor and an n-type organic semiconductor.

The stacked structure includes a stacked structure in which the p-type organic semiconductor, the mixture (bulk hetero structure) of the p-type organic semiconductor and the n-type organic semiconductor, and the n-type organic semiconductor are each stacked. In addition, the stacked structure includes a stacked structure in which the p-type organic semiconductor and the mixture (bulk hetero structure) of the p-type organic semiconductor and the n-type organic semiconductor are each stacked. Further, the stacked structure includes a stacked structure in which the n-type organic semiconductor and the mixture (bulk hetero structure) of the p-type organic semiconductor and the n-type organic semiconductor are each stacked. It is to be noted that the stacking order of the stacked structure may be changed as appropriate.

Examples of the p-type organic semiconductor may include a naphthalene derivative, an anthracene derivative, a phenanthrene derivative, a pyrene derivative, a perylene derivative, a tetracene derivative, a pentacene derivative, a quinacridone derivative, a thiophene derivative, a thienothiophene derivative, a benzothiophene derivative, a benzothienobenzothiophene derivative, a triallylamine derivative, a carbazole derivative, a perylene derivative, a picene derivative, a chrysene derivative, a fluoranthene derivative, a phthalocyanine derivative, a subphthalocyanine derivative, a subporphyrazine derivative, a metal complex including a heterocyclic compound as a ligand, a polythiophene derivative, a polybenzothiadiazole derivative, and a polyfluorene derivative.

Examples of the n-type organic semiconductor include a fullerene and a fullerene derivative ((e.g., fullerenes (higher fullerenes) such as C60, C70, or C74, endohedral fullerene, etc.), or a fullerene derivative (e.g., a fullerene fluoride, a PCBM fullerene compound, a fullerene multimer, etc.)), an organic semiconductor having HOMO and LUMO larger (deeper) than the p-type organic semiconductor, and a transparent inorganic metal oxide.

As the n-type organic semiconductor, there may be specifically used a heterocyclic compound containing a nitrogen atom, an oxygen atom, or a sulfur atom. Examples of the heterocyclic compound include organic molecules including, as a portion of a molecular skeleton, a pyridine derivative, a pyrazine derivative, a pyrimidine derivative, a triazine derivative, a quinoline derivative, a quinoxaline derivative, an isoquinoline derivative, an acridine derivative, a phenazine derivative, a phenanthroline derivative, a tetrazole derivative, a pyrazole derivative, an imidazole derivative, a thiazole derivative, an oxazole derivative, an imidazole derivative, a benzimidazol derivative, a benzotriazole derivative, a benzoxazole derivative, a benzoxazole derivative, a carbazole derivative, a benzofuran derivative, a dibenzofuran derivative, a subporphyrazine derivative, a polyphenylene vinylene derivative, a polybenzothiadiazole derivative, a polyfluorene derivative, and the like, an organic metal complex, and a subphthalocyanine derivative.

Examples of groups and the like included in the fullerene derivative include: halogen atoms; a straight-chain, branched, or cyclic alkyl group or phenyl group; a group including a straight-chain or condensed aromatic compound; a group including halide; a partial fluoroalkyl group; a perfluoroalkyl group; a silylalkyl group; a silylalkoxy group; an arylsilyl group; an arylsulfanyl group; an alkylsulfanyl group; an arylsulfonyl group; an alkylsulfonyl group; an arylsulfide group; an alkylsulfide group; an amino group; an alkylamino group; an arylamino group; a hydroxy group; an alkoxy group; an acylamino group; an acyloxy group; a carbonyl group; a carboxy group; a carboxamide group; a carboalkoxy group; an acyl group; a sulfonyl group; a cyano group; a nitro group; a group including chalcogenide; a phosphine group; a phosphon group; and derivatives thereof.

A thickness of the organic photoelectric conversion layer 63 formed from an organic material is, but not limited to, 1×10⁻⁸ m or more and 5×10⁻⁷ m or less, for example. The thickness of the organic photoelectric conversion layer 63 is, preferably, 2.5×10⁻⁸ m or more and 3×10⁻⁷ m or less, and more preferably, 2.5×10⁻⁸ m or more and 2×10⁻⁷ m or less. The thickness of the organic photoelectric conversion layer 63 is still more preferably, 1×10⁻⁷ m or more and 1.8×10⁻⁷ m or less.

It is to be noted that the organic semiconductors are often classified into p-type and n-type. The p-type means that holes are easily transportable. The n-type means that electrons are easily transportable. Therefore, the organic semiconductor is not limited to the interpretation that it has holes or electrons as majority carriers of thermal excitation, as in inorganic semiconductors.

Further, in the first embodiment, the second photoelectric converter 60 is configured to generate electric charge through photoelectric conversion of light having a green wavelength as a second wavelength range. The wavelength of green light is, for example, 500 nm or more and 585 nm or less.

As a material to form the organic photoelectric conversion layer 63 of the second photoelectric converter 60, there may be used, for example, a rhodamine-based dye, a merocyanine-based dye, a quinacridone derivative, a subphthalocyanine-based dye (a subphthalocyanine derivative), and the like.

It is to be noted that, in a case where the second photoelectric converter 60 photoelectrically converts light having a blue wavelength, as the organic material of the organic photoelectric conversion layer, there may be used, for example, a coumaric acid dye, tris-8-hydroxyquinoline aluminum (Alq3), a merocyanine-based dye, and the like.

In addition, in a case where the second photoelectric converter 60 photoelectrically convers light having a red wavelength, as the organic material of the organic photoelectric conversion layer, there may be used, for example, a phthalocyanine-based dye, a subphthalocyanine-based dye (subphthalocyanine derivative), and the like.

Further, the second photoelectric converter 60 may be constructed by an inorganic photoelectric conversion layer in place of the organic photoelectric conversion layer 63. In this case, as an inorganic material that constructs the inorganic photoelectric conversion layer, there may be used crystalline silicon, amorphous silicon, microcrystalline silicone, crystalline selenium, amorphous selenium, a chalcopyrite-based compound, or a group III-V compound semiconductor.

Examples of the chalcopyrite-based compound include CIGS (CuInGaSe), CIS (CuInSe₂), CuInS₂, CuAlS₂, CuAlSe₂, CuGaS₂, CuGaSe₂, AgAlS₂, AgAlSe₂, AgInS₂, and AgInSe₂.

Examples of the group III-V compound semiconductor include GaAs, InP, AlGaAs, InGaP, AlGaInP, and InGaAsP. Further examples of the group III-V compound semiconductor include CdSe, CdS, In₂Se₃, In₂S₃, Bi₂Se₃, Bi₂S₃, ZnSe, ZnS, PbSe, and PbS.

Additionally, quantum dots including these materials are also usable for the organic photoelectric conversion layer 63.

In addition, the organic photoelectric conversion layer 63 may be configured by a stacked structure of a lower semiconductor layer and an upper photoelectric conversion layer, although illustration is omitted. Providing the organic photoelectric conversion layer 63 with the lower semiconductor layer enables the organic photoelectric conversion layer 63 to prevent recombination during charge accumulation, thus making it possible to improve transfer efficiency of electric charge to the charge accumulation/transfer layer 62. Further, it is possible to effectively suppress generation of a dark current.

For the upper photoelectric conversion layer, selection may be appropriately made from various materials to form the organic photoelectric conversion layer 63 described above.

Meanwhile, for the lower semiconductor layer, it is preferable to use a material having a large bandgap value (e.g., a bandgap value of 3.0 eV or more) and having higher mobility than that of a material forming the organic photoelectric conversion layer 63. Specifically, it may be possible to use an organic semiconductor material such as an oxide semiconductor material such as IGZO, transition metal dichalcogenide, silicon carbide, diamond, graphene, a carbon nano-tube, a condensed polycyclic hydrocarbon compound, and a condensed heterocyclic compound.

In addition, for the lower semiconductor layer, it may be possible to use a material having a larger ionization potential than an ionization potential of the material forming the organic photoelectric conversion layer 63, in a case where electric charge to be accumulated is an electron.

Meanwhile, for the lower semiconductor layer, it may be possible to use a material having a smaller electron affinity than an electron affinity of the material forming the organic photoelectric conversion layer 63, in a case where electric charge to be accumulated is a hole.

In addition, it is preferable, for the material forming the lower semiconductor layer, to have an impurity concentration of 1×10¹⁸ cm⁻³ or less, for example. The lower semiconductor layer may have a monolayer structure or a multilayer structure. In addition, the material forming the lower semiconductor layer may vary between a region corresponding to the first electrode 61 and a region corresponding to the floating diffusion FD2.

### (7-3) Configuration of Second Electrode 64

The second electrode 64 is provided on the organic photoelectric conversion layer 63 on a side opposite to the first electrode 61. The second electrode 64 is used as a common electrode or an upper electrode, and is provided across a plurality of pixels 10. The second electrode 64 is coupled to a power supply voltage line VOU (see FIG. 2). A fixed voltage is supplied to the second electrode 64.

The second electrode 64 is formed by an electrode material having electrical conductivity and having transparency, as with the first electrode 61. The second electrode 64 is formed by, for example, an electrode material such as ITO or IZO. In addition, the second electrode 64 may be formed by one or more electrode materials selected from among IGZO, IAZO, ITZO, IGSiO, ZnO, AZO, and GZO.

The second electrode 64 has, for example, a film thickness of 10 nm or more and 100 nm or less.

### (7-4) Configuration of Electric Charge Accumulation/Transfer Layer 62

The charge accumulation/transfer layer 62 is provided between the first electrode 61 and the organic photoelectric conversion layer 63. To describe this in detail, the organic photoelectric conversion layer 63 is provided above the first electrode 61 with an insulator with no reference numeral interposed therebetween. The charge accumulation/transfer layer 62 here is provided across a plurality of pixels 10.

Here, the insulator with no reference numeral is used as a gate insulating film. For the insulator, for example, one or more selected from among SiO₂, SiON, AIO, and HfO are used.

The charge accumulation/transfer layer 62 accumulates electric charge generated by photoelectric conversion of light in the second photoelectric converter 60. The charge accumulation/transfer layer 62 is coupled to a through electrode (refer to a reference numeral 531 in FIG. 2). The through electrode forms the floating diffusion FD2 (see FIG. 2). That is, electric charge generated in the charge accumulation/transfer layer 62 is transferred to the pixel circuit PC2 (see FIG. 2).

The charge accumulation/transfer layer 62 is formed by an oxide semiconductor that is a transparent semiconductor. For the charge accumulation/transfer layer 62, for example, IGZO including indium (In), gallium (Ga), zinc (Zn), and oxygen (O) is used. In addition, for the charge accumulation/transfer layer 62, IAZO including In, aluminum (Al), Zn, and O or ITZO including In, tin (Sn), Zn, and O may also be used. Further, for the charge accumulation/transfer layer 62, it may also be possible to use one or more semiconductor materials selected from among IGSiO, ZnO, AZO, GZO, ITO, and IZO.

The charge accumulation/transfer layer 62 has, for example, a thickness of 10 nm or more and 100 nm or less.

### (8) Configuration of Optical Lens 80

The optical lens 80 is provided in the optical system region 8. The optical lens 80 is provided on the second electrode 64 on a side opposite to the organic photoelectric conversion layer 63 with the sealing region 7 interposed therebetween.

Here, a plurality of sealing layers 70 is provided in the sealing region 7. The sealing layers 70 are formed by, for example, one or more sealing materials selected from among AlO, SiN, and SiON.

Although not illustrated, the optical lens 80 is formed in a circular shape in a plan view for each of the pixels 10. In addition, the optical lens 80 is formed in a curved shape that curves toward a light incident side to condense the incident light L1 in a side view.

That is, the optical lens 80 is what is called on-chip lens, and is integrally formed for each of the pixels 10 or across a plurality of pixels 10. The optical lens 80 is formed by a transparent resin material, for example.

An antireflection layer 81 is formed on a surface of the optical lens 80. The antireflection layer 81 is formed by SiO₂, for example.

### (9) Configuration of Partition Wall 9

In the solid-state imaging device 1 according to the first embodiment, as illustrated in FIG. 3, a partition wall 9 is provided in a region corresponding to between the adjacent optical filters 40 of the pixels 10.

Detailed description is given. The partition wall 9 is provided from a surface of the base 2 to between the optical filters 40 in the thickness direction of the optical filter 40 that is the arrow-Z direction. In other words, the partition wall 9 is provided from the surface of the base 2 to a surface, on a side of the second photoelectric converter 60, of the optical filter 40. In the partition wall 9, light leakage into the adjacent pixels 10 is smaller than in the insulator 41 that surrounds the side surface of the optical filter 40.

Here, for example, one or more inorganic material selected from among SiN, SiO₂, SiON, and TiSiO, or one or more resin-based materials selected from among a styrene-based resin, an acrylic-based resin, a styrene-acrylic copolymer-based resin, and a siloxane-based resin are used for the insulator 41.

The partition wall 9 includes two or more media.

One of the media is a reflector that reflects light that is to be leakage light to the adjacent pixel 10 of the incident light L1 as reflected light L2 to thereby prevent leakage light and condense the reflected light L2 into the pixel 10. For the reflector, it may be possible to use one or more metal materials having light reflectivity selected from among Al, W, Ag, Rh, and Cu, or a metal material having light reflectivity and high light absorptivity.

Another medium is an absorber or a low refractor.

The absorber absorbs light that is to be leakage light to the adjacent pixel 10 of the incident light L1. For the absorber, the metal material having high light absorptivity exemplified as the reflector described above is used.

The low refractor reduces light leakage into the adjacent pixel 10 by changing a refractive index of light that is to be leakage light to the adjacent pixel 10. For the low refractor, it may be possible to use a material having a lower refractive index than a refractive index of the insulator 41, specifically, a resin-based material having a refractive index of higher than 1.0 and lower than or equal to 1.7.

In addition, examples of the low refractor include a vacuum gap, a gap filled with air, a gap filled with an inert gas. Examples of the inert gas include N₂, Ar, and the like.

That is, the partition wall 9 includes, for example, two kinds of media, that is, the reflector, and the absorber or the low refractor provided on the reflector on a side of the insulator 41. In addition, the partition wall 9 may include two kinds of media, that is, the absorber and the low refractor provided on the absorber on the side of the insulator 41.

Further, the partition wall 9 may include three kinds of media, that is, the reflector, the absorber, and the low refractor.

### [Manufacturing Method of Solid-State Imaging Device 1]

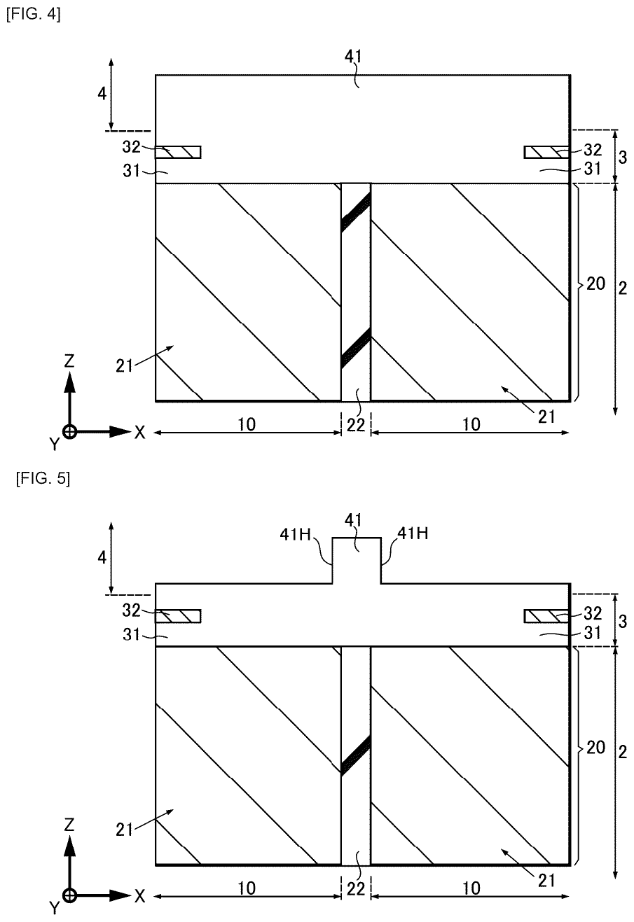

Next, description is given of a manufacturing method of the solid-state imaging device 1 described above with reference to FIGS. 4 to 10. FIGS. 4 to 10 illustrate an example of a series of step cross-sections for describing the manufacturing method of the solid-state imaging device 1 according to the first embodiment.

First, the base 2 is prepared (see FIG. 4). The base 2 is formed by the unillustrated circuit substrate and the semiconductor substrate 20 stacked on the circuit substrate. The first photoelectric converter 21 is formed for each of the pixels 10 in the semiconductor substrate 20. In addition, the pixel separation region 22 is formed in a region corresponding to between the pixels 10 in the semiconductor substrate 20.

Subsequently, the wiring region 3 is formed on the semiconductor substrate 20 of the base 2.

Next, as illustrated in FIG. 4, the insulator 41 that is to be the filter region 4 is formed on the wiring region 3. The insulator 41 is formed by, for example, SiO₂. The insulator 41 has, for example, a film thickness of 300 nm or more and 1100 nm or less.

As illustrated in FIG. 5, an opening 41H is formed for each of the pixels 10 in the insulator 41. The opening 41H is to be filled with the optical filter 40 in a later step. The opening 41H is formed by, for example, dry etching using an unillustrated etching mask.

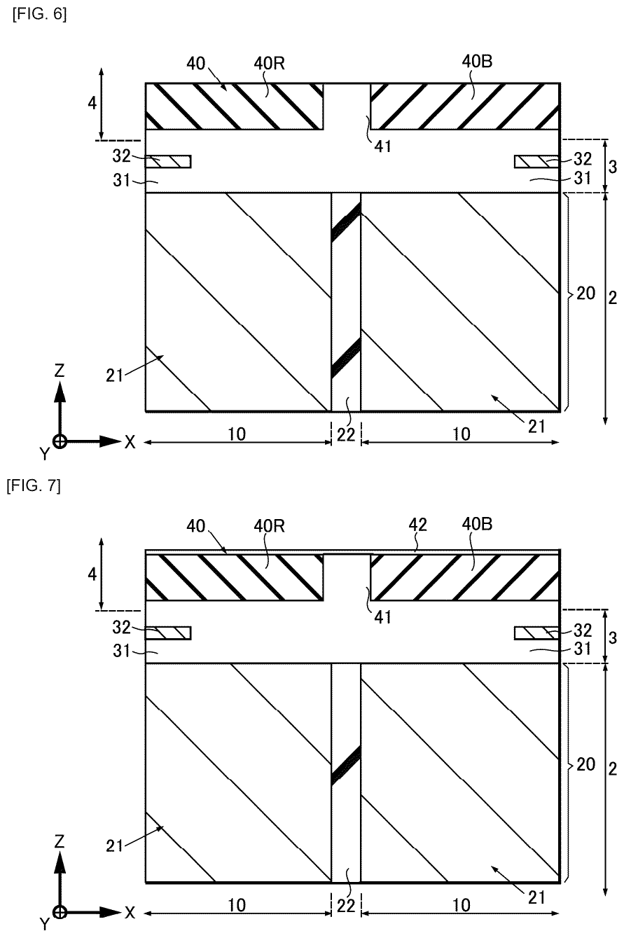

As illustrated in FIG. 6, the optical filter 40 is formed in the opening 51H. Here, as the optical filter 40, the red filter 40R and the blue filter 40B are formed. The insulator 41 remains around the side surface of the optical filter 40.

As illustrated in FIG. 7, the insulator 42 that covers the optical filter 40 is formed. The insulator 42 is formed by, for example, SiN. A film of SiN is formed using a sputtering method or a chemical vapor deposition (CVD: Chemical Vapor Deposition) method.

As illustrated in FIG. 8, a grove 91H is formed in each of the insulator 41 and the insulator 31 in a region corresponding to between the optical filters 40. The groove 91H is formed by, for example, dry etching using an unillustrated etching mask. For example, the groove 91H is so formed as not to reach the base 2.

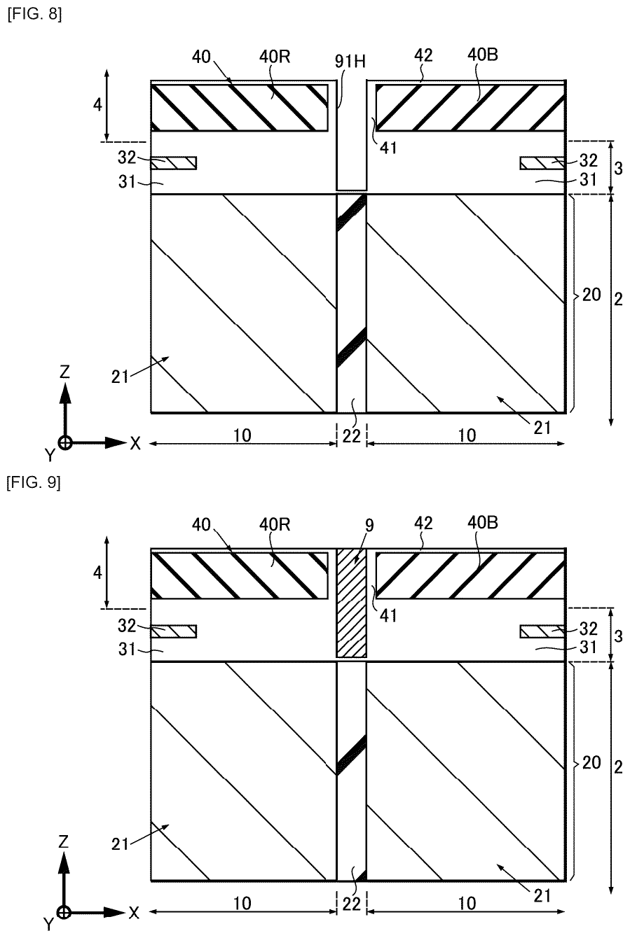

As illustrated in FIG. 9, the partition wall 9 is formed in the groove 91H by, for example, two or more kinds of media. That is, the partition wall 9 is formed by two or more of the reflector, the absorber, the low refractor that have been described above. The partition wall 9 is formed using, for example, a sputtering method or a CVD method.

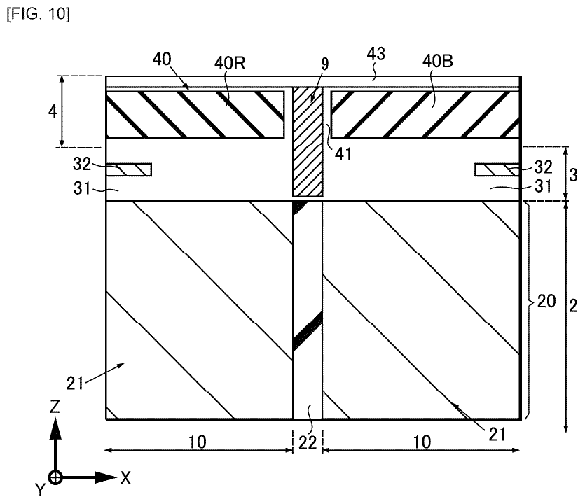

As illustrated in FIG. 10, an insulator 43 is formed on the insulator 42 to cover the partition wall 9. The insulator 43 is formed by, for example, SiO₂. A surface of the insulator 43 is planarized to reduce step heights of the optical filter 40, the partition wall 9, and the like. For example, a chemical mechanical polishing (CMP: Chemical Mechanical Polishing) method is used for planarization.

Subsequently, the wiring region 5, the photoelectric conversion region 6 including the second photoelectric converter 60, the sealing region 7, and the optical system region 8 are each formed in order on the filter region 4 (see FIG. 3),

After the end of a series of steps, the manufacturing method of the solid-state imaging device 1 according to the first embodiment ends to complete the solid-state imaging device 1.

### Workings and Effects

As illustrated in FIGS. 1 to 3, the solid-state imaging device 1 according to the first embodiment includes the pixel 10 including the first photoelectric converter 21, the optical filter 40, and the second photoelectric converter 60. The plurality of pixels is arranged.

The first photoelectric converter 21 is provided in the base 2, and converts light in the first wavelength range into electric charge. The optical filter 40 is provided on the first photoelectric converter 21 on a side opposite to the base 2, and has the side surface surrounded by the insulator 41. The optical filter 40 allows the light in the first wavelength range to pass therethrough. The second photoelectric converter 60 is provided on the optical filter 40 on the side opposite to the first photoelectric converter 21. The second photoelectric converter 60 converts light in the second wavelength range different from the first wavelength range into electric charge. Here, the solid-state imaging device 1 further includes the partition wall 9. The partition wall 9 is provided in a region corresponding to between the adjacent optical filters 40 of the pixels 10. Further, in the partition wall 9, light leakage is smaller than light leakage in the insulator 41.

Accordingly, the solid-state imaging device 1 including two or more stages including the first photoelectric converter 21 and the second photoelectric converter 60 includes the partition wall 9, which makes it possible to effectively reduce or prevent leakage of the incident light L1 into the adjacent pixels 10. Accordingly, it is possible to provide the solid-state imaging device 1 having a superior light reception characteristic with no color mixture.

In addition, in the solid-state imaging device 1, as illustrated in FIG. 3, the partition wall 9 includes two or more kinds of media. This makes it possible to more effectively reduce or prevent leakage of the incident light L1 into the adjacent pixels 10.

Further, in the solid-state imaging device 1, the partition wall 9 includes the reflector that reflects light. In addition, the partition wall 9 includes the absorber that absorbs light. In addition, the partition wall 9 includes the low refractor having a lower refractive index than that of the insulator 41. As the low refractor, a vacuum gap or a gap filled with air or an inert gas is included.

Accordingly, it is possible to more effectively reduce or prevent leakage of the incident light L1 into the adjacent pixels 10.

In addition, in the solid-state imaging device 1, as illustrated in FIG. 3, the partition wall 9 is provided from the base 2 to a position reaching the optical filter 40.

Accordingly, it is possible to effectively reduce or prevent leakage, into the adjacent pixels 10, of the incident light L1 incident on a side of the base 2 from the optical filter 40.

### 2. Second Embodiment

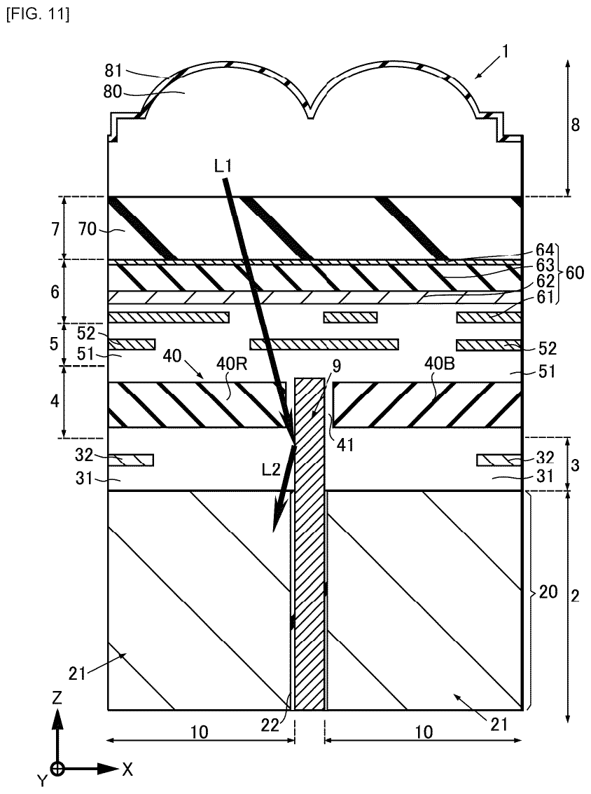

Description is given of the solid-state imaging device 1 according to the second embodiment of the present disclosure with reference to FIG. 11.

It is to be noted that, in the second embodiment and the subsequent embodiments, components the same or substantially the same as the components of the solid-state imaging device 1 according to the first embodiment are denoted by the same reference numerals, and redundant descriptions are omitted.

### [Configuration of Solid-State Imaging Device 1]

FIG. 11 illustrates an example of a longitudinal cross-sectional configuration of the pixel 10.

As illustrated in FIG. 11, in the solid-state imaging device 1 according to the second embodiment, the partition wall 9 is provided in the base 2 and from the base 2 to a position reaching the optical filter 40 in the solid-state imaging device 1 according to the first embodiment.

To describe this in detail, as with the partition wall 9 of the solid-state imaging device 1 according to the first embodiment, the partition wall 9 is provided from the surface of the base 2 to the surface, on the side of the second photoelectric converter 60, of the optical filter 40, and further extends into the base 2. In the base 2, the partition wall 9 is provided between the first photoelectric converters 21 at a position corresponding to between the adjacent pixels 10. The partition wall 9 is provided to overlap the pixel separation region 22.

Components other than the above-described components are the same or substantially the same as the components of the solid-state imaging device 1 according to the first embodiment.

### Workings and Effects

In the solid-state imaging device 1 according to the second embodiment, it is possible to obtain workings and effects similar to the workings and effects obtained by the solid-state imaging device 1 according to the first embodiment.

In addition, in the solid-state imaging device 1, as illustrated in FIG. 11, the partition wall 9 is provided in the base 2 and from the base 2 to the position reaching the optical filter 40, which makes it possible to effectively reduce or prevent leakage of the incident light L1 into the adjacent pixels 10 also in a thickness direction of the base 2.

### 3. Third Embodiment

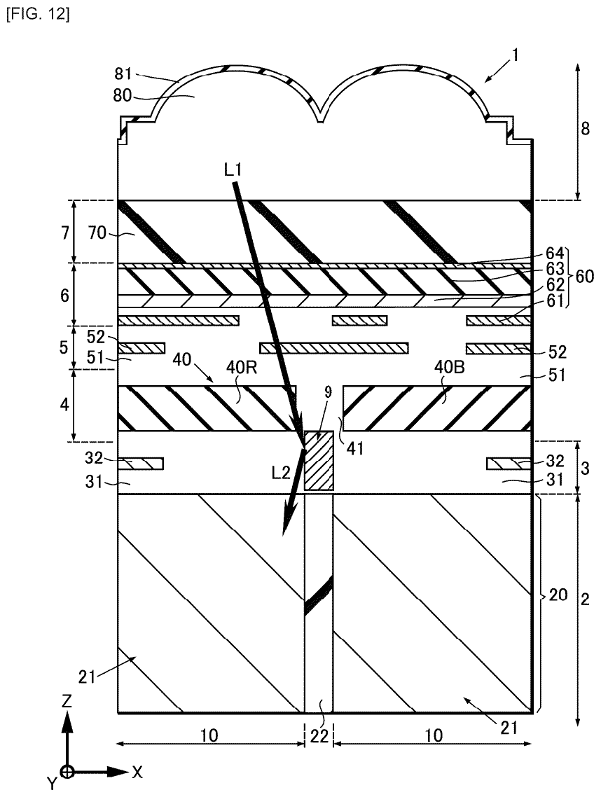

Description is given of the solid-state imaging device 1 according to the third embodiment of the present disclosure with reference to FIG. 12.

### [Configuration of Solid-State Imaging Device 1]

FIG. 12 illustrates an example of a longitudinal cross-sectional configuration of the pixel 10.

As illustrated in FIG. 12, in the solid-state imaging device 1 according to the third embodiment, the partition wall 9 is provided between the base 2 and the optical filter 40 in the solid-state imaging device 1 according to the first embodiment. To describe this in detail, the partition wall 9 is provided in the wiring region 3. The wiring region 3 is a region in which the incident light L1 having passed through the optical filter 40 directly leaks into the first photoelectric converter 21 of the adjacent pixel 10. Accordingly, the partition wall 9 is provided only in the wiring region 3 that is a minimum region.

Components other than the above-described components are the same or substantially the same as the components of the solid-state imaging device 1 according to the first embodiment.

### Workings and Effects

In the solid-state imaging device 1 according to the third embodiment, it is possible to obtain workings and effects similar to the workings and effects obtained by the solid-state imaging device 1 according to the first embodiment.

In addition, in the solid-state imaging device 1, as illustrated in FIG. 12, just providing the partition wall 9 only in a minimum region between the base 2 and the optical filter 40 makes it possible to effectively reduce or prevent leakage of the incident light L1 into the adjacent pixels 10.

### 4. Fourth Embodiment

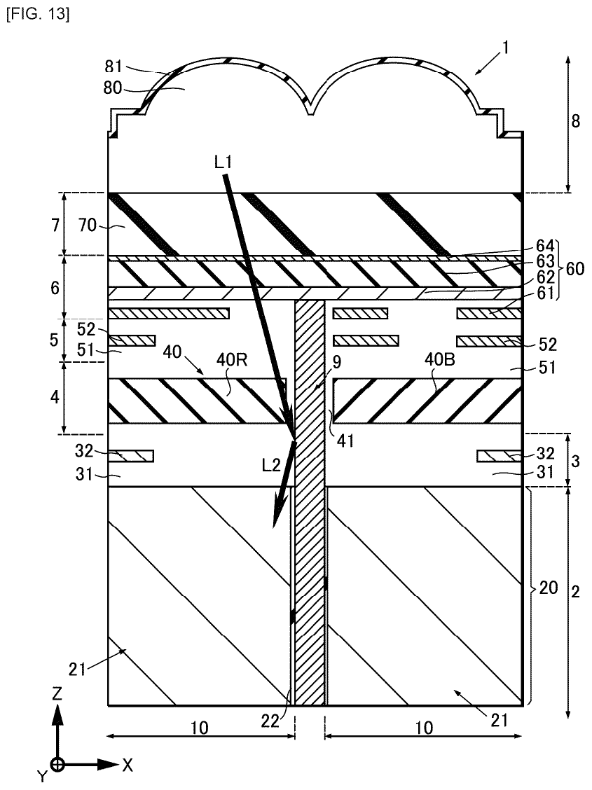

Description is given of the solid-state imaging device 1 according to the fourth embodiment of the present disclosure with reference to FIG. 13.

### [Configuration of Solid-State Imaging Device 1]

FIG. 13 illustrates an example of a longitudinal cross-sectional configuration of the pixel 10.

As illustrated in FIG. 13, in the solid-state imaging device 1 according to the fourth embodiment, the partition wall 9 is further provided from the optical filter 40 to a position reaching the second photoelectric converter 60 in the solid-state imaging device 1 according to the second embodiment.

Components other than the above-described components are the same or substantially the same as the components of the solid-state imaging device 1 according to the second embodiment.

### Workings and Effects

In the solid-state imaging device 1 according to the fourth embodiment, it is possible to obtain workings and effects similar to the workings and effects obtained by the solid-state imaging device 1 according to the second embodiment.

In addition, in the solid-state imaging device 1, as illustrated in FIG. 13, the partition wall 9 is provided also from the optical filter 40 to the position reaching the second photoelectric converter 60, which makes it possible to effectively reduce or prevent leakage of the incident light L1 into the adjacent pixels 10 in a wide range in the thickness direction of the base 2.

### 5. Fifth Embodiment

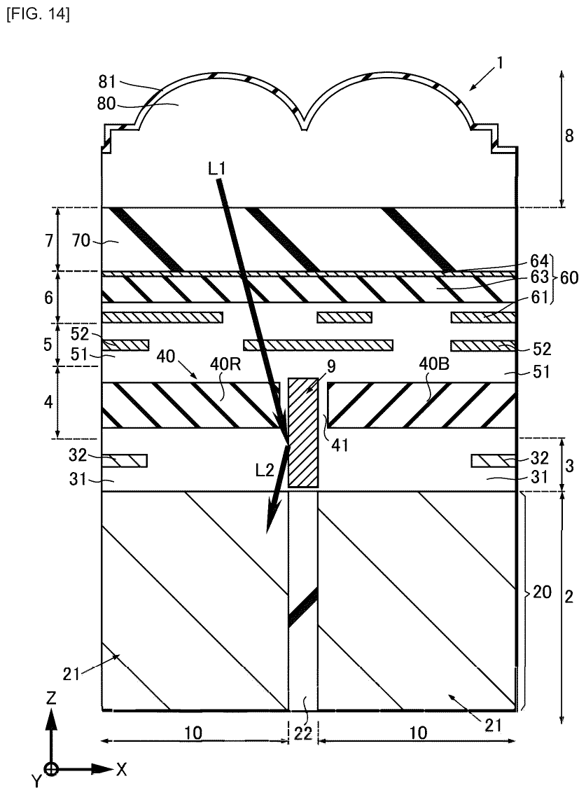

Description is given of the solid-state imaging device 1 according to the fifth embodiment of the present disclosure with reference to FIG. 14.

### [Configuration of Solid-State Imaging Device 1]

FIG. 14 illustrates an example of a longitudinal cross-sectional configuration of the pixel 10.

As illustrated in FIG. 14, in the solid-state imaging device 1 according to the fifth embodiment, the charge accumulation/transfer layer 62 of the second photoelectric converter 60 in the solid-state imaging device 1 according to the first embodiment is not provided. The present technology is applicable to a structure in which the second photoelectric converter 60 is not provided.

Components other than the above-described components are the same or substantially the same as the components of the solid-state imaging device 1 according to the first embodiment.

### Workings and Effects

In the solid-state imaging device 1 according to the fifth embodiment, it is possible to obtain workings and effects similar to the workings and effects obtained by the solid-state imaging device 1 according to the first embodiment.

In addition, in the solid-state imaging device 1, as illustrated in FIG. 14, even if the structure of the second photoelectric converter 60 is changed, it is possible to effectively reduce or prevent leakage of the incident light L1 into the adjacent pixels 10.

### 6. Sixth Embodiment

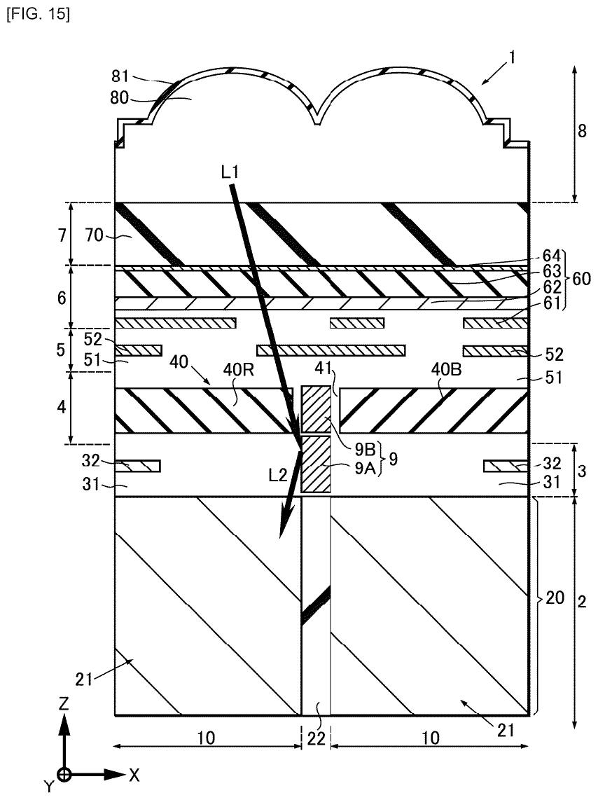

Description is given of the solid-state imaging device 1 according to the sixth embodiment of the present disclosure with reference to FIG. 15.

### [Configuration of Solid-State Imaging Device 1]

FIG. 15 illustrates an example of a longitudinal cross-sectional configuration of the pixel 10.

As illustrated in FIG. 15, in the solid-state imaging device 1 according to the sixth embodiment, the partition wall 9 is divided into a plurality of partition walls in the thickness direction of the optical filter 40 in the solid-state imaging device 1 according to the first embodiment. To describe this in detail, the partition wall 9 includes a partition wall 9A provided in the wiring region 3 and a partition wall 9B provided in the filter region 4.

Components other than the above-described components are the same or substantially the same as the components of the solid-state imaging device 1 according to the first embodiment.

### Workings and Effects

In the solid-state imaging device 1 according to the sixth embodiment, it is possible to obtain workings and effects similar to the workings and effects obtained by the solid-state imaging device 1 according to the first embodiment.

In addition, in the solid-state imaging device 1, as illustrated in FIG. 15, the partition wall 9 is formed by the partition wall 9A and the partition wall 9B that are divided in the thickness direction of the optical filter 40. The partition wall 9A is formed in the insulator 31 in the wiring region 3, which reduces an etching processing amount (an etching depth) of the insulator 31. In addition, the partition wall 9B is formed in the insulator 41 in the filter region 4, which reduces an etching processing amount (an etching depth) of the insulator 41.

Accordingly, it is possible to improve processing accuracy of the partition wall 9.

### 7. Seventh Embodiment

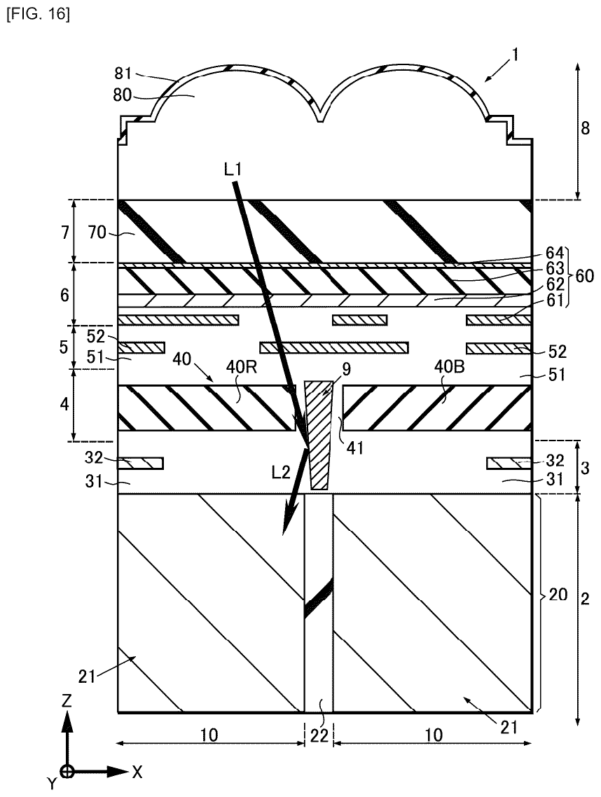

Description is given of the solid-state imaging device 1 according to the seventh embodiment of the present disclosure with reference to FIG. 16.

### [Configuration of Solid-State Imaging Device 1]

FIG. 16 illustrates an example of a longitudinal cross-sectional configuration of the pixel 10.

As illustrated in FIG. 16, in the solid-state imaging device 1 according to the seventh embodiment, a width dimension of the partition wall 9 decreases from a side of the second photoelectric converter 60 to a side of the first photoelectric converter 21 in the solid-state imaging device 1 according to the first embodiment. That is, a cross-sectional shape of the partition wall 9 is formed in an inverted trapezoidal shape in a side view. A surface, opposed to the side surface of the optical filter 40, of the partition wall 9 is formed in an inclined surface.

Components other than the above-described components are the same or substantially the same as the components of the solid-state imaging device 1 according to the first embodiment.

### Workings and Effects

In the solid-state imaging device 1 according to the seventh embodiment, it is possible to obtain workings and effects similar to the workings and effects obtained by the solid-state imaging device 1 according to the first embodiment.

In addition, in the solid-state imaging device 1, as illustrated in FIG. 16, the width dimension of the partition wall 9 decreases from the side of the second photoelectric converter 60 to the side of the first photoelectric converter 21.

Accordingly, it is possible to increase an opening area of the wiring region 3, which makes it possible to effectively reduce or prevent leakage of the incident light L1 into the adjacent pixels 10 while improving layout efficiency of the wiring 32 in the wiring region 3.

### 8. Eighth Embodiment

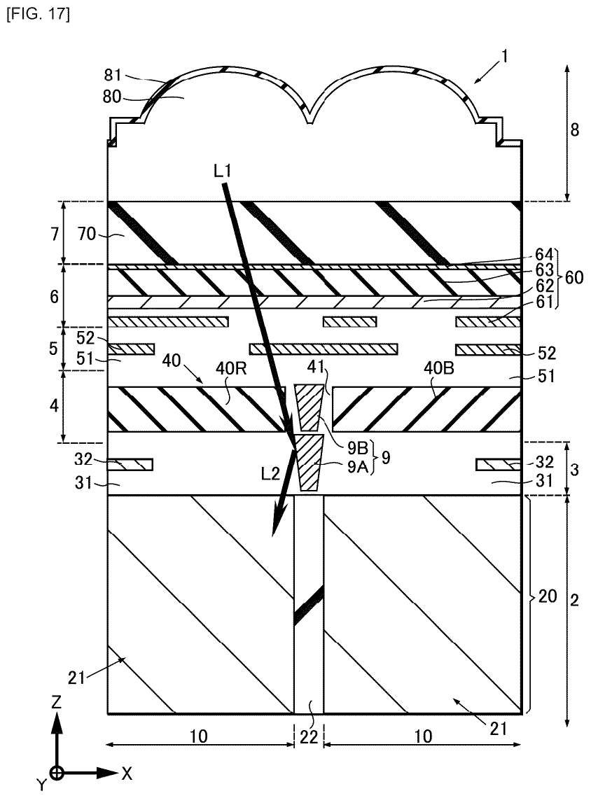

Description is given of the solid-state imaging device 1 according to the eighth embodiment of the present disclosure with reference to FIG. 17.

### [Configuration of Solid-State Imaging Device 1]

FIG. 17 illustrates an example of a longitudinal cross-sectional configuration of the pixel 10.

As illustrated in FIG. 17, in the solid-state imaging device 1 according to the eighth embodiment, the solid-state imaging device 1 according to the sixth embodiment and the solid-state imaging device 1 according to the seventh embodiment are combined. To describe this in detail, the partition wall 9 includes a plurality of partition walls, that is, the partition wall 9A and the partition wall 9B that are divided in the thickness direction of the optical filter 40. Further, a width dimension of each of the partition wall 9A and the partition wall 9B decreases from the side of the second photoelectric converter 60 to the side of the first photoelectric converter 21.

Components other than the above-described components are the same or substantially the same as the components of the solid-state imaging device 1 according to the sixth embodiment and the solid-state imaging device 1 according to the seventh embodiment.

### Workings and Effects

In the solid-state imaging device 1 according to the eighth embodiment, it is possible to obtain workings and effects including a combination of the workings and effects obtained by the solid-state imaging device 1 according to the sixth embodiment and the workings and effects obtained by the solid-state imaging device 1 according to the seventh embodiment.

### 9. Ninth Embodiment

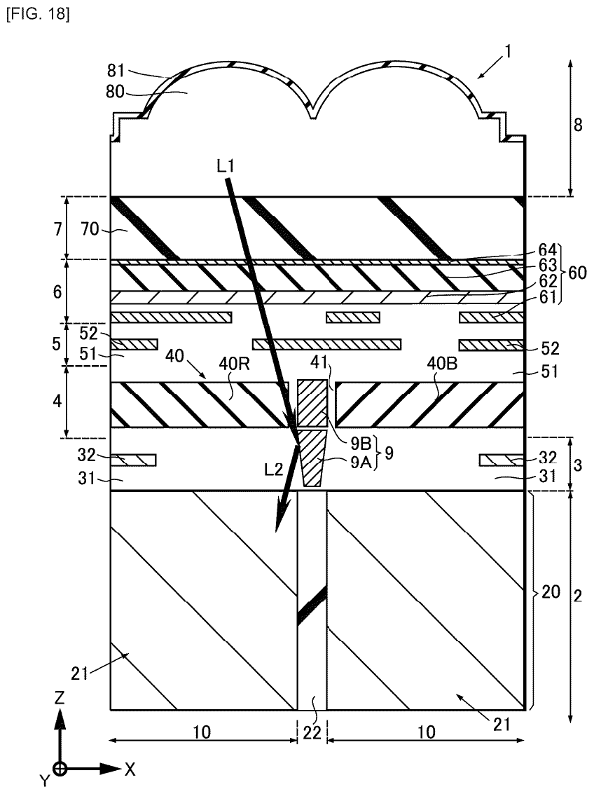

Description is given of the solid-state imaging device 1 according to the ninth embodiment of the present disclosure with reference to FIG. 18.

### [Configuration of Solid-State Imaging Device 1]

FIG. 18 illustrates an example of a longitudinal cross-sectional configuration of the pixel 10.

As illustrated in FIG. 18, the solid-state imaging device 1 according to the ninth embodiment is a first application example of the solid-state imaging device 1 according to the eighth embodiment.

To describe this in detail, the partition wall 9 includes a plurality of partition walls, that is, the partition wall 9A and the partition wall 9B that are divided in the thickness direction of the optical filter 40. Further, the width dimension of the partition wall 9A decreases from the side of the second photoelectric converter 60 to the side of the first photoelectric converter 21. Meanwhile, the width dimension of the partition wall 9B is constant from the side of the second photoelectric converter 60 to the side of the first photoelectric converter 21.

Components other than the above-described components are the same or substantially the same as the components of the solid-state imaging device 1 according to the eighth embodiment.

### Workings and Effects

In the solid-state imaging device 1 according to the ninth embodiment, it is possible to obtain workings and effects similar to the workings and effects obtained by the solid-state imaging device 1 according to the eighth embodiment.

### 10. Tenth Embodiment

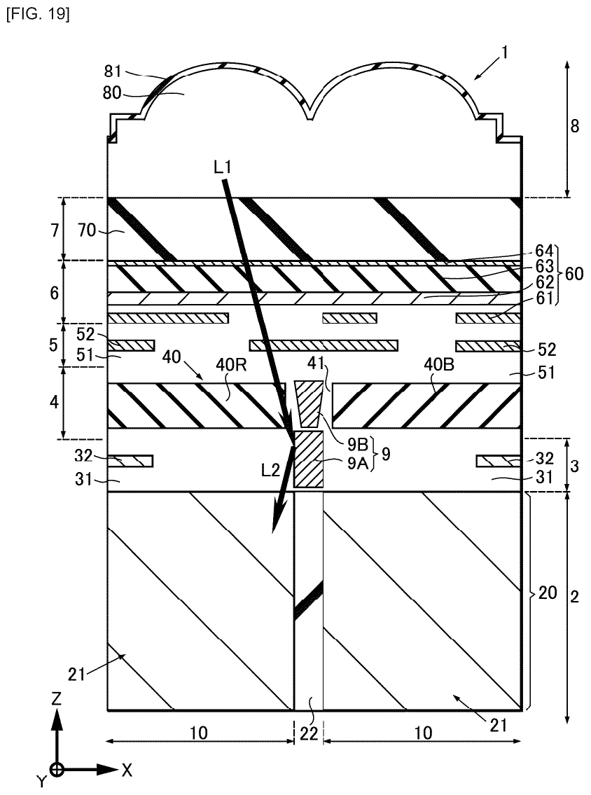

Description is given of the solid-state imaging device 1 according to the tenth embodiment of the present disclosure with reference to FIG. 19.

### [Configuration of Solid-State Imaging Device 1]

FIG. 19 illustrates an example of a longitudinal cross-sectional configuration of the pixel 10.

As illustrated in FIG. 19, the solid-state imaging device 1 according to the tenth embodiment is a second application example of the solid-state imaging device 1 according to the eighth embodiment. To describe this in detail, the partition wall 9 includes a plurality of partition walls, that is, the partition wall 9A and the partition wall 9B that are divided in the thickness direction of the optical filter 40. Further, the width dimension of the partition wall 9A is constant from the side of the second photoelectric converter 60 to the side of the first photoelectric converter 21.

Meanwhile, the width dimension of the partition wall 9B decreases from the side of the second photoelectric converter 60 to the side of the first photoelectric converter 21.

Components other than the above-described components are the same or substantially the same as the components of the solid-state imaging device 1 according to the eighth embodiment.

### Workings and Effects

In the solid-state imaging device 1 according to the tenth embodiment, it is possible to obtain workings and effects similar to the workings and effects obtained by the solid-state imaging device 1 according to the eighth embodiment.

### 11. Eleventh Embodiment

Description is given of the solid-state imaging device 1 according to the eleventh embodiment of the present disclosure with reference to FIG. 20.

### [Configuration of Solid-State Imaging Device 1]

FIG. 20 illustrates an example of a planar configuration of the pixel 10.

As illustrated in FIG. 20, in the solid-state imaging device 1 according to the eleventh embodiment, the through electrode 53 is provided in addition to the partition wall 9 in any of the solid-state imaging devices 1 according to the first to tenth embodiments. The through electrode 53 is either the first through electrode 531 or the second through electrode 532.

As illustrated in FIG. 2 described above, the first through electrode 531 configures the floating diffusion FD2 that couples the one electrode of the second photoelectric converter 60 and the pixel circuit PC2 to each other. In addition, the second through electrode 532 configures the coupling wiring that couples the other electrode of the second photoelectric converter 60 and the drive signal line VOA to each other.

Returning to FIG. 20, in the eleventh embodiment, the unit pixel PU includes two pixels 10 arranged in the arrow-X direction and two pixels 10 arranged in the arrow-Y direction, and is constructed by a total of four pixels 10.

With respect to such an arrangement layout of the unit pixel PU, the partition wall 9 provided in a region corresponding to between two pixels 10 arranged adjacent to each other in the arrow-X direction extends in the arrow-Y direction. In addition, the partition wall 9 provided in a region corresponding to between two pixels 10 arranged adjacent to each other in the arrow-Y direction extends in the arrow-X direction.

Further, the through electrode 53 is provided in a middle where the partition wall 9 extends. In other words, the through electrode 53 is provided coincidently on the extension of the partition wall 9.

To describe this in more detail, the partition wall 9 extends in each of the arrow-Y direction and the arrow-X direction, and is provided in a grid pattern in a plan view. The through electrode 53 is provided at an intersection part (a grid-point part) of the partition wall 9 extending in each of the arrow-Y direction and the arrow-X direction.

In the eleventh embodiment, the through electrode 53 is spaced apart from an extension end of the partition wall 9. A spacing dimension SD is a dimension shorter than or equal to a wavelength of light. In the solid-state imaging device 1, the wavelength of blue light is the shortest; therefore, to effectively reduce or prevent light leakage from between the through electrode 53 and the partition wall 9, the spacing dimension SD is set to 400 nm or less.

Components other than the above-described components are the same or substantially the same as the components of any of the solid-state imaging devices 1 according to the first to tenth embodiments.

### Workings and Effects

In the solid-state imaging device 1 according to the eleventh embodiment, it is possible to obtain workings and effects similar to the workings and effects obtained by any of the solid-state imaging devices 1 according to the first to tenth embodiments.

In addition, in the solid-state imaging device 1, as illustrated in FIG. 20, the through electrode 53 is provided in the middle where the partition wall 9 extends. As with the partition wall 9, the through electrode 53 is provided using a region corresponding to between the adjacent pixels 10, which makes it possible to expand a light reception area of the pixel 10.

In addition, in the solid-state imaging device 1, as illustrated in FIG. 20, the through electrode 53 is spaced apart from the extension end of the partition wall 9. The spacing dimension SD is a dimension shorter than or equal to the wavelength of light. For example, the spacing dimension SD is 400 nm or less.

The through electrode 53 and the partition wall 9 are spaced apart from each other, which makes it possible to process the through electrode 53 and the partition wall 9 independently of each other in manufacturing of the solid-state imaging device 1, for example. In addition, the spacing dimension SD is set to the dimension shorter than or equal to the wavelength of light, which makes it possible to effectively reduce or prevent leakage of the incident light L1 into the adjacent pixels 10.

### 12. Twelfth Embodiment

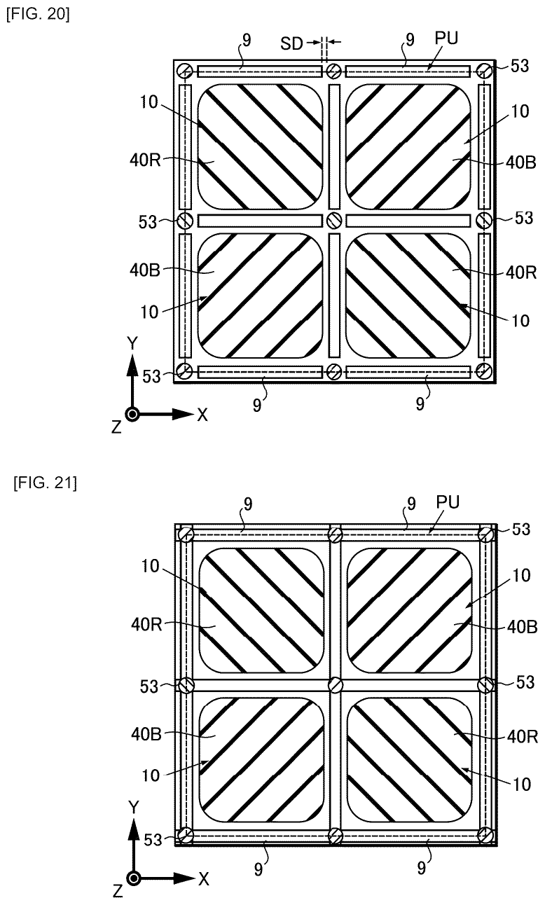

Description is given of the solid-state imaging device 1 according to the twelfth embodiment of the present disclosure with reference to FIG. 21.

### [Configuration of Solid-State Imaging Device 1]

FIG. 21 illustrates an example of a planar configuration of the pixel 10.

As illustrated in FIG. 21, in the solid-state imaging device 1 according to the twelfth embodiment, the partition wall 9 and the through electrode 53 are provided in contact with each other in the solid-state imaging device 1 according to the eleventh embodiment.

Components other than the above-described components are the same or substantially the same as the components of the solid-state imaging device 1 according to the eleventh embodiment.

### Workings and Effects

In the solid-state imaging device 1 according to the twelfth embodiment, it is possible to obtain workings and effects similar to the workings and effects obtained by the solid-state imaging device 1 according to the eleventh embodiment.

### 13. Thirteenth Embodiment

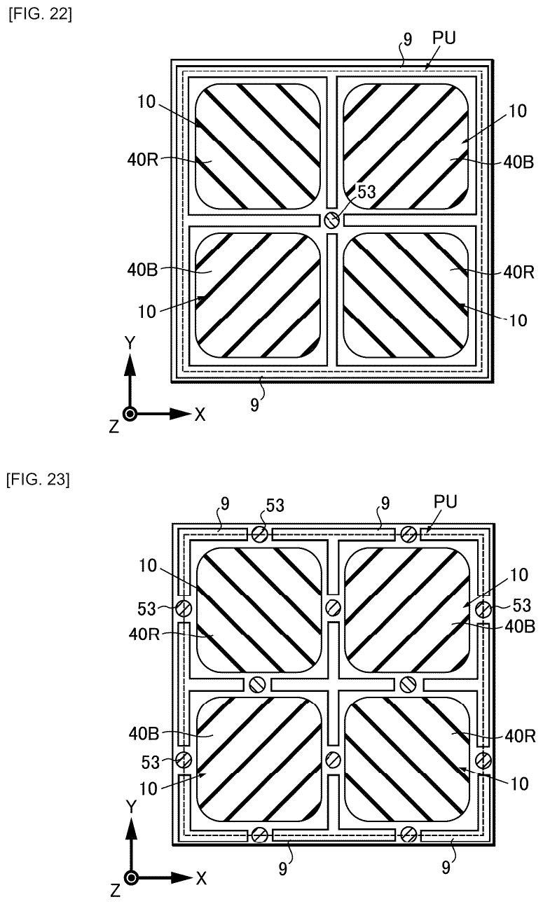

Description is given of the solid-state imaging device 1 according to the thirteenth embodiment of the present disclosure with reference to FIG. 22.

### [Configuration of Solid-State Imaging Device 1]

FIG. 22 illustrates an example of a planar configuration of the pixel 10.

As illustrated in FIG. 22, in the solid-state imaging device 1 according to the thirteenth embodiment, one through electrode 53 is provided at a middle position of the unit pixel PU in the solid-state imaging device 1 according to the eleventh embodiment. That is, one through electrode 53 shared by four pixels 10 of the unit pixel PU is provided.

Components other than the above-described components are the same or substantially the same as the components of the solid-state imaging device 1 according to the eleventh embodiment.

### Workings and Effects

In the solid-state imaging device 1 according to the thirteenth embodiment, it is possible to obtain workings and effects similar to the workings and effects obtained by the solid-state imaging device 1 according to the eleventh embodiment.

### 14. Fourteenth Embodiment

Description is given of the solid-state imaging device 1 according to the fourteenth embodiment of the present disclosure with reference to FIG. 23.

### [Configuration of Solid-State Imaging Device 1]

FIG. 23 illustrates an example of a planar configuration of the pixel 10.

As illustrated in FIG. 23, in the solid-state imaging device 1 according to the fourteenth embodiment, the through electrode 53 is provided at a middle part of the pixel 10 in a middle where the partition wall 9 extends in the solid-state imaging device 1 according to the eleventh embodiment. The middle part of the pixel 10 means a middle position of one side of the pixel 10 formed in a rectangular shape in a plan view.

Components other than the above-described components are the same or substantially the same as the components of the solid-state imaging device 1 according to the eleventh embodiment.

### Workings and Effects

In the solid-state imaging device 1 according to the fourteenth embodiment, it is possible to obtain workings and effects similar to the workings and effects obtained by the solid-state imaging device 1 according to the eleventh embodiment.

### 15. Fifteenth Embodiment

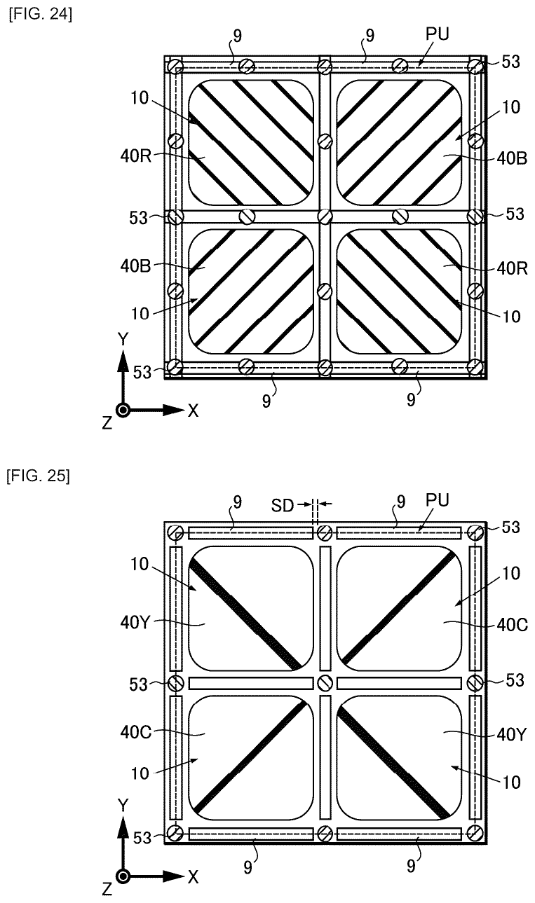

Description is given of the solid-state imaging device 1 according to the fifteenth embodiment of the present disclosure with reference to FIG. 24.

### [Configuration of Solid-State Imaging Device 1]

FIG. 24 illustrates an example of a planar configuration of the pixel 10.

As illustrated in FIG. 24, in the solid-state imaging device 1 according to the fifteenth embodiment, the solid-state imaging device 1 according to the twelfth embodiment and the solid-state imaging device 1 according to the fourteenth embodiment are combined. To describe this in detail, the through electrodes 53 are provided at the intersection part of the partition wall 9 and at the middle part of the pixel 10.

Components other than the above-described components are the same or substantially the same as the components of the solid-state imaging device 1 according to the twelfth embodiment and the solid-state imaging device 1 according to the fourteenth embodiment.

### Workings and Effects

In the solid-state imaging device 1 according to the fifteenth embodiment, it is possible to obtain workings and effects including a combination of the workings and effects obtained by the solid-state imaging device 1 according to the twelfth embodiment and the workings and effects obtained by the solid-state imaging device 1 according to the fourteenth embodiment.

### 16. Sixteenth Embodiment

Description is given of the solid-state imaging device 1 according to the sixteenth embodiment of the present disclosure with reference to FIG. 25.

### [Configuration of Solid-State Imaging Device 1]

FIG. 25 illustrates an example of a planar configuration of the pixel 10.

As illustrated in FIG. 25, in the solid-state imaging device 1 according to the sixteenth embodiment, the configuration of the optical filter 40 is changed in the solid-state imaging device 1 according to the eleventh embodiment. To describe this in detail, the unit pixel PU includes two pixels 10 that each have a yellow filter 40Y and are provided on one diagonal line, and two pixels 10 that each have a cyan filter 40C and are provided on another diagonal line.

Components other than the above-described components are the same or substantially the same as the components of the solid-state imaging device 1 according to the eleventh embodiment.

### Workings and Effects

In the solid-state imaging device 1 according to the sixteenth embodiment, it is possible to obtain workings and effects similar to the workings and effects obtained by the solid-state imaging device 1 according to the eleventh embodiment.

### 17. Seventeenth Embodiment

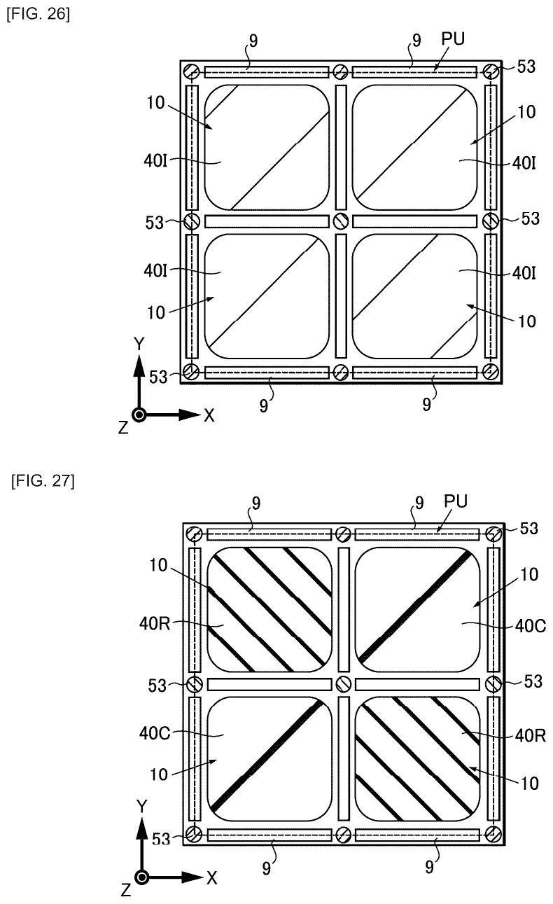

Description is given of the solid-state imaging device 1 according to the seventeenth embodiment of the present disclosure with reference to FIG. 26.

### [Configuration of Solid-State Imaging Device 1]

FIG. 26 illustrates an example of a planar configuration of the pixel 10.

As illustrated in FIG. 26, in the solid-state imaging device 1 according to the seventeenth embodiment, the configuration of the optical filter 40 is changed in the solid-state imaging device 1 according to the eleventh embodiment. To describe this in detail, the unit pixel PU includes four pixels 10 each having an infrared pass filter 40I.

Components other than the above-described components are the same or substantially the same as the components of the solid-state imaging device 1 according to the eleventh embodiment.

### Workings and Effects

In the solid-state imaging device 1 according to the seventeenth embodiment, it is possible to obtain workings and effects similar to the workings and effects obtained by the solid-state imaging device 1 according to the eleventh embodiment.

### 18. Eighteenth Embodiment

Description is given of the solid-state imaging device 1 according to the eighteenth embodiment of the present disclosure with reference to FIG. 27.

### [Configuration of Solid-State Imaging Device 1]

FIG. 27 illustrates an example of a planar configuration of the pixel 10.

As illustrated in FIG. 27, in the solid-state imaging device 1 according to the eighteenth embodiment, the configuration of the optical filter 40 is changed in the solid-state imaging device 1 according to the eleventh embodiment. To describe this in detail, the unit pixel PU includes two pixels 10 that each have the red filter 40R and are provided on one diagonal line, and two pixels 10 that each have the cyan filter 40C and are provided on another diagonal line.

Components other than the above-described components are the same or substantially the same as the components of the solid-state imaging device 1 according to the eleventh embodiment.

### Workings and Effects

In the solid-state imaging device 1 according to the eighteenth embodiment, it is possible to obtain workings and effects similar to the workings and effects obtained by the solid-state imaging device 1 according to the eleventh embodiment.

### 19. Example of Application to Mobile Body

The technology (present technology) according to the present disclosure is applicable to various products. For example, the technology according to the present disclosure may be achieved in the form of an apparatus to be mounted to a mobile body of any kind such as an automobile, an electric vehicle, a hybrid electric vehicle, a motorcycle, a bicycle, a personal mobility, an airplane, a drone, a vessel, and a robot.

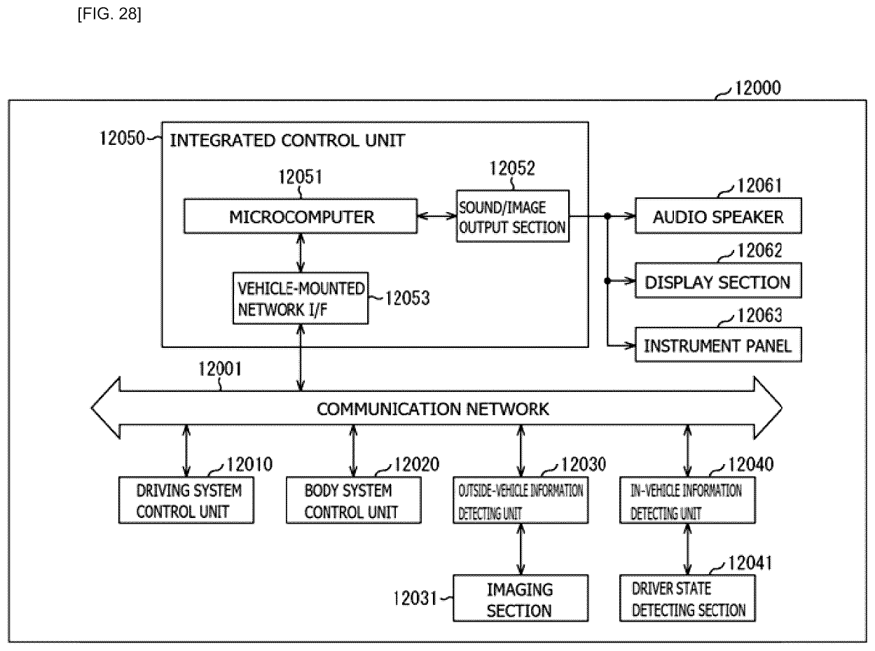

FIG. 28 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 28, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 28, an audio speaker 12061, a display section 12062, and an instrument panel 12063 are illustrated as the output device. The display section 12062 may, for example, include at least one of an on-board display and a head-up display.

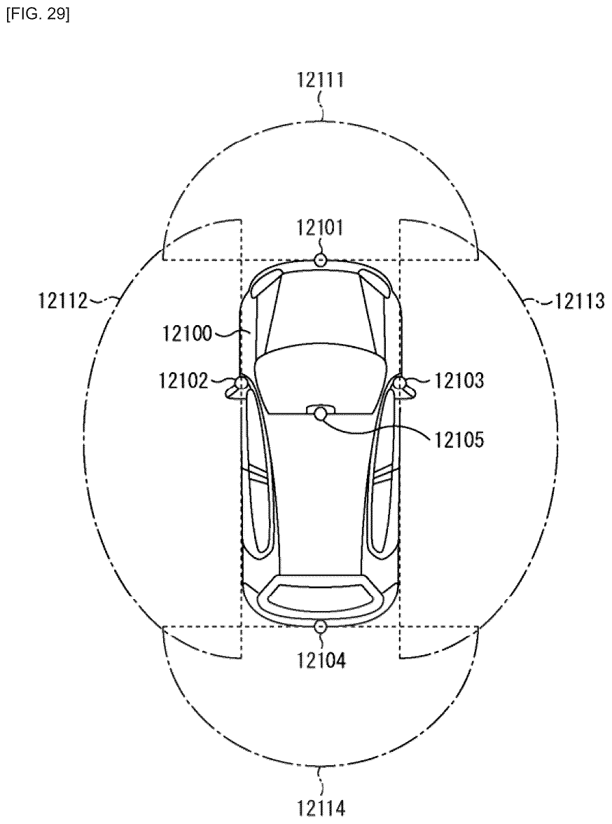

FIG. 29 is a diagram depicting an example of the installation position of the imaging section 12031.

In FIG. 29, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 29 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

The description has been given hereinabove of one example of the vehicle control system, to which the technology according to the present disclosure may be applied. The technology according to the present disclosure may be applied to the imaging section 12031 among the configurations described above. The application of the technology according to the present disclosure to the imaging section 12031 enables achievement of the imaging section 12031 of a simpler configuration.

### 20. Example of Application to Endoscopic Surgery System

The technology according to the present disclosure (present technology) is applicable to various products. For example, the technology according to the present disclosure may be applied to an endoscopic surgery system.

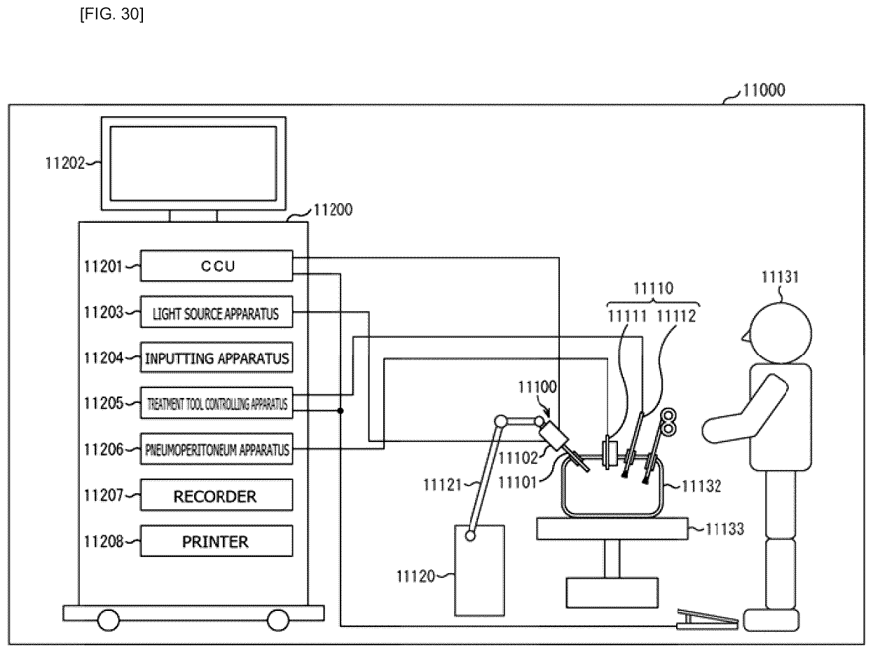

FIG. 30 is a view depicting an example of a schematic configuration of an endoscopic surgery system to which the technology according to an embodiment of the present disclosure (present technology) can be applied.

In FIG. 30, a state is illustrated in which a surgeon (medical doctor) 11131 is using an endoscopic surgery system 11000 to perform surgery for a patient 11132 on a patient bed 11133. As depicted, the endoscopic surgery system 11000 includes an endoscope 11100, other surgical tools 11110 such as a pneumoperitoneum tube 11111 and an energy device 11112, a supporting arm apparatus 11120 which supports the endoscope 11100 thereon, and a cart 11200 on which various apparatus for endoscopic surgery are mounted.

The endoscope 11100 includes a lens barrel 11101 having a region of a predetermined length from a distal end thereof to be inserted into a body cavity of the patient 11132, and a camera head 11102 connected to a proximal end of the lens barrel 11101. In the example depicted, the endoscope 11100 is depicted which includes as a rigid endoscope having the lens barrel 11101 of the hard type. However, the endoscope 11100 may otherwise be included as a flexible endoscope having the lens barrel 11101 of the flexible type.

The lens barrel 11101 has, at a distal end thereof, an opening in which an objective lens is fitted. A light source apparatus 11203 is connected to the endoscope 11100 such that light generated by the light source apparatus 11203 is introduced to a distal end of the lens barrel 11101 by a light guide extending in the inside of the lens barrel 11101 and is irradiated toward an observation target in a body cavity of the patient 11132 through the objective lens. It is to be noted that the endoscope 11100 may be a forward-viewing endoscope or may be an oblique-viewing endoscope or a side-viewing endoscope.

An optical system and an image pickup element are provided in the inside of the camera head 11102 such that reflected light (observation light) from the observation target is condensed on the image pickup element by the optical system. The observation light is photo-electrically converted by the image pickup element to generate an electric signal corresponding to the observation light, namely, an image signal corresponding to an observation image. The image signal is transmitted as RAW data to a CCU 11201.

The CCU 11201 includes a central processing unit (CPU), a graphics processing unit (GPU) or the like and integrally controls operation of the endoscope 11100 and a display apparatus 11202. Further, the CCU 11201 receives an image signal from the camera head 11102 and performs, for the image signal, various image processes for displaying an image based on the image signal such as, for example, a development process (demosaic process).

The display apparatus 11202 displays thereon an image based on an image signal, for which the image processes have been performed by the CCU 11201, under the control of the CCU 11201.

The light source apparatus 11203 includes a light source such as, for example, a light emitting diode (LED) and supplies irradiation light upon imaging of a surgical region to the endoscope 11100.

An inputting apparatus 11204 is an input interface for the endoscopic surgery system 11000. A user can perform inputting of various kinds of information or instruction inputting to the endoscopic surgery system 11000 through the inputting apparatus 11204. For example, the user would input an instruction or a like to change an image pickup condition (type of irradiation light, magnification, focal distance or the like) by the endoscope 11100.

A treatment tool controlling apparatus 11205 controls driving of the energy device 11112 for cautery or incision of a tissue, sealing of a blood vessel or the like. A pneumoperitoneum apparatus 11206 feeds gas into a body cavity of the patient 11132 through the pneumoperitoneum tube 11111 to inflate the body cavity in order to secure the field of view of the endoscope 11100 and secure the working space for the surgeon. A recorder 11207 is an apparatus capable of recording various kinds of information relating to surgery. A printer 11208 is an apparatus capable of printing various kinds of information relating to surgery in various forms such as a text, an image or a graph.

It is to be noted that the light source apparatus 11203 which supplies irradiation light when a surgical region is to be imaged to the endoscope 11100 may include a white light source which includes, for example, an LED, a laser light source or a combination of them. Where a white light source includes a combination of red, green, and blue (RGB) laser light sources, since the output intensity and the output timing can be controlled with a high degree of accuracy for each color (each wavelength), adjustment of the white balance of a picked up image can be performed by the light source apparatus 11203. Further, in this case, if laser beams from the respective RGB laser light sources are irradiated time-divisionally on an observation target and driving of the image pickup elements of the camera head 11102 are controlled in synchronism with the irradiation timings. Then images individually corresponding to the R, G and B colors can be also picked up time-divisionally. According to this method, a color image can be obtained even if color filters are not provided for the image pickup element.

Further, the light source apparatus 11203 may be controlled such that the intensity of light to be outputted is changed for each predetermined time. By controlling driving of the image pickup element of the camera head 11102 in synchronism with the timing of the change of the intensity of light to acquire images time-divisionally and synthesizing the images, an image of a high dynamic range free from underexposed blocked up shadows and overexposed highlights can be created.

Further, the light source apparatus 11203 may be configured to supply light of a predetermined wavelength band ready for special light observation. In special light observation, for example, by utilizing the wavelength dependency of absorption of light in a body tissue to irradiate light of a narrow band in comparison with irradiation light upon ordinary observation (namely, white light), narrow band observation (narrow band imaging) of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source apparatus 11203 can be configured to supply such narrow-band light and/or excitation light suitable for special light observation as described above.

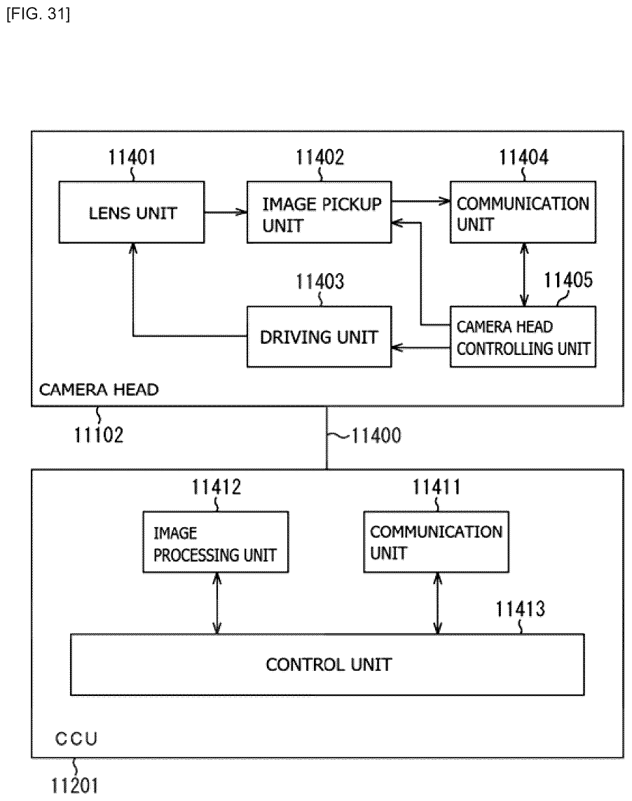

FIG. 31 is a block diagram depicting an example of a functional configuration of the camera head 11102 and the CCU 11201 depicted in FIG. 30.

The camera head 11102 includes a lens unit 11401, an image pickup unit 11402, a driving unit 11403, a communication unit 11404 and a camera head controlling unit 11405. The CCU 11201 includes a communication unit 11411, an image processing unit 11412 and a control unit 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The number of image pickup elements which is included by the image pickup unit 11402 may be one (single-plate type) or a plural number (multi-plate type). Where the image pickup unit 11402 is configured as that of the multi-plate type, for example, image signals corresponding to respective R, G and B are generated by the image pickup elements, and the image signals may be synthesized to obtain a color image. The image pickup unit 11402 may also be configured so as to have a pair of image pickup elements for acquiring respective image signals for the right eye and the left eye ready for three dimensional (3D) display. If 3D display is performed, then the depth of a living body tissue in a surgical region can be comprehended more accurately by the surgeon 11131. It is to be noted that, where the image pickup unit 11402 is configured as that of stereoscopic type, a plurality of systems of lens units 11401 are provided corresponding to the individual image pickup elements.

Further, the image pickup unit 11402 may not necessarily be provided on the camera head 11102. For example, the image pickup unit 11402 may be provided immediately behind the objective lens in the inside of the lens barrel 11101.

The driving unit 11403 includes an actuator and moves the zoom lens and the focusing lens of the lens unit 11401 by a predetermined distance along an optical axis under the control of the camera head controlling unit 11405. Consequently, the magnification and the focal point of a picked up image by the image pickup unit 11402 can be adjusted suitably.

The communication unit 11404 includes a communication apparatus for transmitting and receiving various kinds of information to and from the CCU 11201. The communication unit 11404 transmits an image signal acquired from the image pickup unit 11402 as RAW data to the CCU 11201 through the transmission cable 11400.

In addition, the communication unit 11404 receives a control signal for controlling driving of the camera head 11102 from the CCU 11201 and supplies the control signal to the camera head controlling unit 11405. The control signal includes information relating to image pickup conditions such as, for example, information that a frame rate of a picked up image is designated, information that an exposure value upon image picking up is designated and/or information that a magnification and a focal point of a picked up image are designated.

It is to be noted that the image pickup conditions such as the frame rate, exposure value, magnification or focal point may be designated by the user or may be set automatically by the control unit 11413 of the CCU 11201 on the basis of an acquired image signal. In the latter case, an auto exposure (AE) function, an auto focus (AF) function and an auto white balance (AWB) function are incorporated in the endoscope 11100.

The camera head controlling unit 11405 controls driving of the camera head 11102 on the basis of a control signal from the CCU 11201 received through the communication unit 11404.

The communication unit 11411 includes a communication apparatus for transmitting and receiving various kinds of information to and from the camera head 11102. The communication unit 11411 receives an image signal transmitted thereto from the camera head 11102 through the transmission cable 11400.

Further, the communication unit 11411 transmits a control signal for controlling driving of the camera head 11102 to the camera head 11102. The image signal and the control signal can be transmitted by electrical communication, optical communication or the like.

The image processing unit 11412 performs various image processes for an image signal in the form of RAW data transmitted thereto from the camera head 11102.

The control unit 11413 performs various kinds of control relating to image picking up of a surgical region or the like by the endoscope 11100 and display of a picked up image obtained by image picking up of the surgical region or the like. For example, the control unit 11413 creates a control signal for controlling driving of the camera head 11102.

Further, the control unit 11413 controls, on the basis of an image signal for which image processes have been performed by the image processing unit 11412, the display apparatus 11202 to display a picked up image in which the surgical region or the like is imaged. Thereupon, the control unit 11413 may recognize various objects in the picked up image using various image recognition technologies. For example, the control unit 11413 can recognize a surgical tool such as forceps, a particular living body region, bleeding, mist when the energy device 11112 is used and so forth by detecting the shape, color and so forth of edges of objects included in a picked up image. The control unit 11413 may cause, when it controls the display apparatus 11202 to display a picked up image, various kinds of surgery supporting information to be displayed in an overlapping manner with an image of the surgical region using a result of the recognition. Where surgery supporting information is displayed in an overlapping manner and presented to the surgeon 11131, the burden on the surgeon 11131 can be reduced and the surgeon 11131 can proceed with the surgery with certainty.

The transmission cable 11400 which connects the camera head 11102 and the CCU 11201 to each other is an electric signal cable ready for communication of an electric signal, an optical fiber ready for optical communication or a composite cable ready for both of electrical and optical communications.

Here, while, in the example depicted, communication is performed by wired communication using the transmission cable 11400, the communication between the camera head 11102 and the CCU 11201 may be performed by wireless communication.

The description has been given above of one example of the endoscopic surgery system, to which the technology according to the present disclosure may be applied. The technology according to the present disclosure may be applied to, for example, the image pickup unit 11402 among the configurations described above. Specifically, in the image pickup unit 11402, a partition wall is provided in a region corresponding to between optical filters adjacent to each other of pixels. The application of the technology according to the present disclosure to the image pickup unit 11402 makes it possible to effectively reduce or prevent leakage of incident light into adjacent pixels.

It is to be noted that although the endoscopic surgery system has been described as an example here, the technology according to the present disclosure may also be applied to, for example, a microscopic surgery system, and the like.

### 21. Other Embodiments

The present technology is not limited to the embodiments described above, and various modifications may be made without departing from the gist of the present technology.

For example, the solid-state imaging devices according to two or more embodiments, among the solid-state imaging devices according to the foregoing first to fourth embodiments, may be combined.

A solid-state imaging device according to a first aspect of the present disclosure includes a plurality of pixels arranged. The pixels each include a first photoelectric converter, an optical filter, and a second photoelectric converter.

The first photoelectric converter is provided in a base, and converts light in a first wavelength range into electric charge. The optical filter is provided on the first photoelectric converter on a side opposite to the base, and has a side surface surrounded by an insulator. The optical filter allows light in the first wavelength range to pass therethrough. The second photoelectric converter is provided on the optical filter on a side opposite to the first photoelectric converter. The second photoelectric converter converts light in a second wavelength range different from the first wavelength range into electric charge.

Here, the solid-state imaging device further includes a partition wall. The partition wall is provided in a region corresponding to between the optical filters adjacent to each other of the pixels, and in the partition wall, light leakage is smaller than light leakage in the insulator.

With such a configuration, the solid-state imaging device includes the partition wall, which makes it possible to effectively reduce or prevent leakage of incident light into adjacent pixels.

A solid-state imaging device according to a second aspect of the present disclosure further includes a through electrode, in the solid-state imaging device according to the first aspect. The through electrode penetrates in a thickness direction of the optical filter from the second photoelectric converter toward a side of the first photoelectric converter. The through electrode is provided in a middle where the partition wall extends.

With such a configuration, the through electrode is provided using a region corresponding to between the pixels adjacent to each other, which makes it possible to expand a light reception area of the pixel.

### Configuration of Present Technology

The present technology has the following configurations. According to the present technology having the following configurations, it is possible, in a solid-state imaging device, to effectively reduce or prevent leakage of incident light into adjacent pixels.

(1)

A solid-state imaging device including:
a plurality of pixels arranged, the pixels each including
   a first photoelectric converter that is provided in a base, and converts light in a first wavelength range into electric charge,
   an optical filter that is provided on the first photoelectric converter on a side opposite to the base, has a side surface surrounded by an insulator, and allows the light in the first wavelength range to pass therethrough, and
   a second photoelectric converter that is provided on the optical filter on a side opposite to the first photoelectric converter, and converts light in a second wavelength range different from the first wavelength range into electric charge; and
   a partition wall that is provided in a region corresponding to between the optical filters adjacent to each other of the pixels, and in which light leakage is smaller than light leakage in the insulator.
      (2)

The solid-state imaging device according to (1), in which the partition wall includes two or more kinds of media.

(3)

The solid-state imaging device according to (1) or (2), in which the partition wall includes a reflector that reflects light.

(4)

The solid-state imaging device according to any one of (1) to (3), in which the partition wall includes an absorber that absorbs light.

(5)

The solid-state imaging device according to any one of (1) to (4), in which the partition wall includes a low refractor having a lower refractive index than a refractive index of the insulator.

(6)

The solid-state imaging device according to any one of (1) to (5), in which the partition wall has a vacuum gap or a gap filled with air or an inert gas.

(7)

The solid-state imaging device according to any one of (1) to (6), in which the partition wall is provided between the base and the optical filter.

(8)

The solid-state imaging device according to any one of (1) to (6), in which the partition wall is provided from the base to a position reaching the optical filter.

(9)

The solid-state imaging device according to any one of (1) to (6), in which the partition wall is provided in the base and from the base to a position reaching the optical filter.

(10)

The solid-state imaging device according to (8) or (9), in which the partition wall is further provided from the optical filter to a position reaching the second photoelectric converter.

(11)

The solid-state imaging device according to any one of (1) to (10), in which the partition wall is divided into a plurality of parts in a thickness direction of the optical filter.

(12)

The solid-state imaging device according to any one of (1) to (11), in which a width dimension of the partition wall decreases from a side of the second photoelectric converter to a side of the first photoelectric converter.

(13)

The solid-state imaging device according to (3) or (4), in which the partition wall includes one or more metal materials selected from among Al, W, Ag, Rh, and Cu.

(14)

The solid-state imaging device according to (5), in which the partition wall includes a resin-based material.

(15)

The solid-state imaging device according to any one of (1) to (14), in which in a region corresponding to between the pixels arranged in a first direction, the partition wall extends in a second direction intersecting with the first direction, and in a region corresponding to between the pixels arranged in the second direction, the partition wall extends in the first direction.

(16)

The solid-state imaging device according to (15), further including a through electrode that penetrates in a thickness direction of the optical filter from the second photoelectric converter toward a side of the first photoelectric converter, in which the through electrode is provided in a middle where the partition wall extends.

(17)

The solid-state imaging device according to (16), in which the through electrode is provided at an intersection part of the partition wall extending in the first direction and the partition wall extending in the second direction.

(18)

The solid-state imaging device according to (16) or (17), in which the through electrode is provided in a middle part of the pixel.

(19)

The solid-state imaging device according to any one of (16) to (18), in which the through electrode is spaced apart from the partition wall by a spacing dimension shorter than or equal to a wavelength of light.

(20)

The solid-state imaging device according to (19), in which the through electrode is spaced apart from the partition wall by a dimension of 400 nm or less.

The present application claims the benefit of Japanese Priority Patent Application JP2022-180029 filed with the Japan Patent Office on Nov. 10, 2022, the entire contents of which are incorporated herein by reference.

It should be understood by those skilled in the art that various modifications, combinations, sub-combinations, and alterations may occur depending on design requirements and other factors insofar as they are within the scope of the appended claims or the equivalents thereof.

1. A solid-state imaging device comprising:
a plurality of pixels arranged, the pixels each including
a first photoelectric converter that is provided in a base, and converts light in a first wavelength range into electric charge,
an optical filter that is provided on the first photoelectric converter on a side opposite to the base, has a side surface surrounded by an insulator, and allows the light in the first wavelength range to pass therethrough, and
a second photoelectric converter that is provided on the optical filter on a side opposite to the first photoelectric converter, and converts light in a second wavelength range different from the first wavelength range into electric charge; and
a partition wall that is provided in a region corresponding to between the optical filters adjacent to each other of the pixels, and in which light leakage is smaller than light leakage in the insulator.

2. The solid-state imaging device according to claim 1, wherein the partition wall includes two or more kinds of media.

3. The solid-state imaging device according to claim 1, wherein the partition wall includes a reflector that reflects light.

4. The solid-state imaging device according to claim 1, wherein the partition wall includes an absorber that absorbs light.

5. The solid-state imaging device according to claim 1, wherein the partition wall includes a low refractor having a lower refractive index than a refractive index of the insulator.

6. The solid-state imaging device according to claim 1, wherein the partition wall has a vacuum gap or a gap filled with air or an inert gas.

7. The solid-state imaging device according to claim 1, wherein the partition wall is provided between the base and the optical filter.

8. The solid-state imaging device according to claim 1, wherein the partition wall is provided from the base to a position reaching the optical filter.

9. The solid-state imaging device according to claim 1, wherein the partition wall is provided in the base and from the base to a position reaching the optical filter.

10. The solid-state imaging device according to claim 8, wherein the partition wall is further provided from the optical filter to a position reaching the second photoelectric converter.

11. The solid-state imaging device according to claim 1, wherein the partition wall is divided into a plurality of parts in a thickness direction of the optical filter.

12. The solid-state imaging device according to claim 1, wherein a width dimension of the partition wall decreases from a side of the second photoelectric converter to a side of the first photoelectric converter.

13. The solid-state imaging device according to claim 3, wherein the partition wall includes one or more metal materials selected from among Al, W, Ag, Rh, and Cu.

14. The solid-state imaging device according to claim 5, wherein the partition wall includes a resin-based material.

15. The solid-state imaging device according to claim 1, wherein
in a region corresponding to between the pixels arranged in a first direction, the partition wall extends in a second direction intersecting with the first direction, and
in a region corresponding to between the pixels arranged in the second direction, the partition wall extends in the first direction.

16. The solid-state imaging device according to claim 15, further comprising a through electrode that penetrates in a thickness direction of the optical filter from the second photoelectric converter toward a side of the first photoelectric converter, wherein
the through electrode is provided in a middle where the partition wall extends.

17. The solid-state imaging device according to claim 16, wherein the through electrode is provided at an intersection part of the partition wall extending in the first direction and the partition wall extending in the second direction.

18. The solid-state imaging device according to claim 16, wherein the through electrode is provided in a middle part of the pixel.

19. The solid-state imaging device according to claim 16, wherein the through electrode is spaced apart from the partition wall by a spacing dimension shorter than or equal to a wavelength of light.

20. The solid-state imaging device according to claim 19, wherein the through electrode is spaced apart from the partition wall by a dimension of 400 nm or less.
